(19) United States
(12) Patent Application Publication
(10) Pub. No.: US 2009/0275157 A1
(43) Pub. Date: Nov. 5, 2009

(54) OPTICAL DEVICE SHAPING

(75) Inventors: Paul N. Winberg, Rollingwood, TX (US); Dung T. Duong, Cedar Park, TX (US); Matthew R. Thomas, Austin, TX (US); Elliot M. Pickering, Austin, TX (US)

Correspondence Address: SPRINKLE IP LAW GROUP, 1301 W. 25TH STREET, SUITE 408, AUSTIN, TX, 78705, US

(73) Assignee: Illumitex, Inc., Austin, TX (US)

(21) Appl. No.: 12/492,599

(22) Filed: Jun. 26, 2009

Related U.S. Application Data
(63) Continuation-in-part of application No. 11/906,194, filed on Oct. 1, 2007.
Application No. 11/906,194 is a continuation-in-part of application No. 11/906,219, filed on Oct. 1, 2007.
(60) Provisional application No. 61/075,972, filed on Jun. 26, 2008.
(60) Provisional application No. 60/827,818, filed on Oct. 2, 2006.
(60) Provisional application No. 60/881,785, filed on Jan. 22, 2007.
(60) Provisional application No. 60/827,818, filed on Oct. 2, 2006.
(60) Provisional application No. 60/881,785, filed on Jan. 22, 2007.

(51) Int. Cl. H01L 21/302

(52) U.S. Cl. 438/29; 257/E21.214

(57) ABSTRACT

Embodiments described herein provide methods for manufacturing an optical device having shaped sidewalls. A desired substrate shape corresponding to an LED or other optical device can be determined. The optical device can have a substrate comprising an exit face and sidewalls positioned and shaped to reflect light to the exit face to allow light to escape the exit face. A substrate material can be shaped based on the desired substrate shape for one or more LEDs. Shaping can be done using a wire saw, etching, ultrasonic shaping or other technique.

### RELATED APPLICATIONS

This application claims the benefit of priority under 35 U.S.C. 119(e) to U.S. Provisional Patent Application No. 61/075,972, entitled “SYSTEM AND METHODS FOR OPTICAL DEVICE SHAPING AND POLISHING” by inventor Winberg, filed Jun. 26, 2008. This application also claims the benefit of priority under 35 U.S.C. 120 as a continuation-in-part of U.S. patent application Ser. No. 11/906,194, entitled “LED SYSTEM AND METHOD” by inventors Duong et al., filed Oct. 1, 2007, and as a continuation-in-part of U.S. patent application Ser. No. 11/906,219, entitled “LED SYSTEM AND METHOD”, by inventors Duong et al., filed Oct. 1, 2007, each of which claim priority under 35 U.S.C. 119(e) to U.S. Provisional Patent Application No. 60/827,818, entitled “SHAPED LIGHT EMITTING DIODES”, by inventors Duong et al., filed Oct. 2, 2006, and to U.S. Provisional Patent Application No. 60/881,785, entitled “SYSTEM AND METHOD FOR A SHAPED SUBSTRATE LED”, by inventors Duong et al., filed Jan. 22, 2007. Each of the above referenced applications is hereby fully incorporated by reference herein.

### TECHNICAL FIELD OF THE INVENTION

This disclosure regards optical devices and in particular light emitting diodes (“LEDs”). More particularly, this disclosure relates to shaping optical devices.

### BACKGROUND

Light emitting diodes (“LEDs”) are ubiquitous in electronics. They are used in digital displays, lighting systems, computers and televisions, cellular telephones and a variety of other devices. Developments in LED technology have led to methods and systems for the generation of white light using one or more LEDs.

Developments in LED technology have led to LEDs that generate more photons and thus more light than previously. The culmination of these two technological developments is that LEDs are being used to supplement or replace many conventional lighting sources, e.g. incandescent, fluorescent or halogen bulbs, much as the transistor replaced the vacuum tube in computers.

LEDs are produced in a number of colors including red, green and blue. One method of generating white light involves the use of red, green and blue LEDs in combination with one another. A lighting source that is made of combinations of red, green and blue (RGB) LEDs will produce what is perceived as white light by the human eye. This occurs because the human eye has three types of color receptors, with each type sensitive to either blue, green or red colors.

A second method of producing white light from LED sources is to create light from a single-color (e.g. blue), short wavelength LED, and impinge a portion of that light onto phosphor or similar photon conversion material. The phosphor absorbs the higher energy, short wavelength light waves, and re-emits lower energy, longer wavelength light. If a phosphor is chosen that emits light in the yellow region (between green and red), for example, the human eye perceives such light as white light. This occurs because the yellow light stimulates both the red and green receptors in the eye. Other materials, such as nano-particles or other similar photo-luminescent materials, may be used to generate white light in much the same way.

White light may also be generated utilizing an ultraviolet (UV) LED and three separate RGB phosphors.

White light may also be generated from a blue LED and a yellow LED and may also be generated utilizing blue, green, yellow and red LEDs in combination.

Current industry practice for construction of LEDs is to use a substrate (typically either single-crystal Sapphire or Silicon Carbide), onto which is deposited layers of materials such as GaN or InGaN. One or more layers (e.g. GaN or InGaN) may allow photon generation and current conduction. Typically, a first layer of Gallium Nitride (GaN) is applied to the surface of the substrate to form a transition region from the crystal structure of the substrate to the crystal structure of doped layers allowing for photon generation or current conduction. This is typically followed by an N-doped layer of GaN. The next layer can be an InGaN, AlGaN, AlInGaN or other compound semiconductor material layer that generates photons and that is doped with the needed materials to produce the desired wavelength of light. The next layer is typically a P doped layer of GaN. This structure is further modified by etching and deposition to create metallic sites for electrical connections to the device.

During the operation of an LED, as in a traditional diode, extra electrons move from an N-type semiconductor to electron holes in a P-type semiconductor. In an LED, photons are released in the compound semiconductor layer to produce light during this process.

In a typical manufacturing process, the substrate is fabricated in wafer form and the layers are applied to a surface of the wafer. Once the layers are doped or etched and all the features have been defined using the various processes mentioned, the individual LEDs are separated from the wafer. The LEDs are typically square or rectangular with straight sides. This can cause significant efficiency losses and can cause the emitted light to have a poor emission pattern. A separate optical device, such as a plastic dome, is often placed over the LED to achieve a more desirable output.

### SUMMARY

This disclosure relates to shaping optical devices to increase light extraction. In particular, the optical device can include sidewalls shaped to direct more light to the exit face of the optical device using total internal reflection while preventing or minimizing total internal reflection at the exit face. Additionally, the optical device can include an exit face with sufficient area to conserve radiance. Various methods can be used to shape a substrate material to within a manufacturing tolerance.

According to one embodiment, a method can comprise providing a desired substrate shape corresponding to an optical device having a substrate comprising an exit face, an interface and a set of sidewalls. The substrate of the optical device can be shaped to increase light extraction. For example, the exit face of the substrate portion of the optical device can have at least 70% of a minimum area necessary to conserve radiance for a desired half-angle of light projected from the optical device.

Furthermore, the optical device can have an interface and the exit face. In addition, the set of sidewalls of the shaped substrate portion of the optical device can be positioned and shaped to cause at least a majority of rays having a straight transmission path from the interface to that sidewall to reflect to the exit face with an angle of incidence at the exit face at less than or equal to a critical angle at the exit face. Based on the desired shape of optical device, a manufacturing method can be applied to a substrate material to shape the substrate material.

Various techniques can be used to shape the optical device including, but not limited to cutting, grinding, ultrasonic machining, ultrasonic cutting, etching, water ablation, laser ablation, particle jet ablation and other techniques.

### BRIEF DESCRIPTION OF THE FIGURES

A more complete understanding of the embodiments and the advantages thereof may be acquired by referring to the following description, taken in conjunction with the accompanying drawings in which like reference numbers indicate like features and wherein:

FIGS. 1A-1B are diagrammatic representations of embodiments of LEDs;

FIG. 2 is a diagrammatic representation of a set of rays traveling from a point to surfaces at different distances from the point;

FIG. 3 provides a diagrammatic representation of a top view of an embodiment of an LED;

FIG. 4A is a diagrammatic representation of a cross-section of a model of an LED for determining sidewall shapes;

FIG. 4B is a diagrammatic representation of an embodiment of a portion of a sidewall of an LED;

FIG. 4C is a diagrammatic representation illustrating that the facets for a sidewall can be defined using a computer program;

FIG. 4D is a diagrammatic representation of one embodiment of an LED with sidewalls shaped to cause TIR so that rays are reflected from the sidewalls to the exit surface;

FIG. 5 is a diagrammatic representation of one embodiment for estimating effective solid angle;

FIGS. 6A-6E are diagrammatic representations describing another embodiment for estimating effective solid angle;

FIG. 7 is a diagrammatic representation of one embodiment of a LED;

FIGS. 8A-8B are diagrammatic representations of embodiments of an array of LEDs;

FIG. 9 is a diagrammatic representation of cutting a substrate using a wire saw and portions thereof;

FIGS. 10-14 are diagrammatic representations of embodiments of a wire saw;

FIG. 15 is a diagrammatic representation of an embodiment of grinding a wafer;

FIGS. 16A-F are diagrammatic representations of an embodiment of cutting a substrate with a grinding wheel and FIGS. 16G-N are diagrammatic representations of additional embodiments of grinding wheels;

FIG. 17 is a diagrammatic representation of an embodiment of etching a wafer;

FIG. 18 is a diagrammatic representation of an embodiment of shaping a substrate using ultrasonic shaping;

FIG. 19 is a diagrammatic representation of an embodiment of laser ablation;

FIG. 20 is a diagrammatic representation of another embodiment of laser ablation;

FIG. 21 is a diagrammatic representation of an embodiment of water jet ablation; and

FIG. 22 is a diagrammatic representation of an embodiment of particle jet ablation.

### DETAILED DESCRIPTION

The disclosure and various features and advantageous details thereof are explained more fully with reference to the exemplary, and therefore non-limiting, embodiments illustrated in the accompanying drawings and detailed in the following description. Descriptions of known starting materials and processes may be omitted so as not to unnecessarily obscure the disclosure in detail. It should be understood, however, that the detailed description and the specific examples, while indicating the preferred embodiments, are given by way of illustration only and not by way of limitation. Various substitutions, modifications, additions and/or rearrangements within the spirit and/or scope of the underlying inventive concept will become apparent to those skilled in the art from this disclosure.

As used herein, the terms “comprises,” “comprising,” “includes,” “including,” “has,” “having” or any other variation thereof, are intended to cover a non-exclusive inclusion. For example, a process, product, article, or apparatus that comprises a list of elements is not necessarily limited to only those elements but may include other elements not expressly listed or inherent to such process, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Additionally, any examples or illustrations given herein are not to be regarded in any way as restrictions on, limits to, or express definitions of, any term or terms with which they are utilized. Instead these examples or illustrations are to be regarded as being described with respect to one particular embodiment and as illustrative only. Those of ordinary skill in the art will appreciate that any term or terms with which these examples or illustrations are utilized encompass other embodiments as well as implementations and adaptations thereof which may or may not be given therewith or elsewhere in the specification and all such embodiments are intended to be included within the scope of that term or terms. Language designating such non-limiting examples and illustrations includes, but is not limited to: “for example,” “for instance,” “e.g.,” “in one embodiment,” and the like.

Reference is now made in detail to the exemplary embodiments of the disclosure, examples of which are illustrated in the accompanying drawings. Wherever possible, like numerals will be used throughout the drawings to refer to like and corresponding parts (elements) of the various drawings.

Embodiments described herein provide systems and methods for shaping an optical device substrate to within an acceptable tolerance of a desired substrate shape. While the example of an LED is used, embodiments can apply to other optical devices that utilize a substrate to guide or gather light. Furthermore, while the sapphire is used as the primary example of a substrate, other substrate materials may also be used including, but not limited to, silicon carbide, glass, diamond or other substrate material known or developed in the art. The desired substrate shape can be defined as discussed below to create an LED with desired optical characteristics. While the desired shape may be based on a particular desired LED shape, the desired shape for shaping methods may account for additional changes or rounding during later polishing stages.

The shaping methods can shape a substrate material to be within an acceptable tolerance of the desired shape. IN one embodiment, the acceptable tolerance can be within plus or minus 20% of the desired shape and even more particularly within 1% of the desired shape. In other embodiments, the shaping method applied shapes the substrate material to within 50 microns and even more particularly within 10 microns of the desired shape. In some cases, the shaping method can also create sidewalls that are polished to a desired smoothness. In other cases, the substrate material can be polished using a separate polishing method. Thus, while the desired shape upon which shaping is based may have, for example, sidewalls positioned and shaped to reflect a certain amount of light to the exit face, the resulting shaped substrate may not achieve such reflection without additional steps such as polishing.

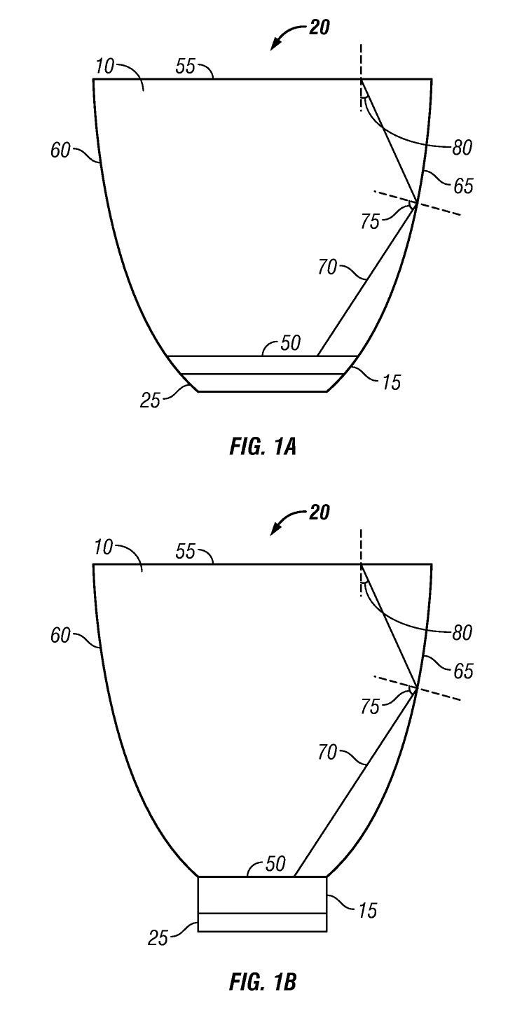

FIGS. 1-8B and the accompanying discussion describe various embodiments of optical devices with shaped substrates. Once the desired substrate shape is determined, the shaping methods can shape the substrate accordingly.

Embodiments of shaped substrate LEDs may be shaped so as to increase or shape the light emission from the LED. According to one embodiment, the substrate is shaped so that all or a supermajority of the light generated by the quantum well region of the LED is transmitted out the exit face of the substrate of the LED. To this end, the exit face can be sized to take into account principles of conservation of radiance. In one embodiment, the exit face may be the minimum size that allows all or a supermajority of the light entering the substrate through the interface between the quantum well region and the substrate (that is, the interface to a non-substrate layer that receives light generated in a light emitting region of the optical device) to exit the exit face, thereby combining the desire to conserve radiance with the desire to reduce size, particularly the size of the exit face. Additionally, the sidewalls of the substrate may be shaped so that reflection or total internal reflection (“TIR”) causes light beams incident on substrate sidewalls to reflect towards the exit face and be incident on the exit face with an angle less than or equal to the critical angle. Consequently, light loss due to TIR at the exit face is reduced or eliminated. In a further embodiment, to insure that light striking a sidewall is reflected within the substrate and does not pass through the sidewall, a sidewall or sidewalls of a substrate may also be coated with a reflective material that reflects light to prevent the exitance of light through the sidewall.

While the etendue equation shows that theoretically 100% of the light that passes from the quantum well region of the LED into the substrate of the LED can exit the substrate through the exit face, various embodiments may cause lesser amounts of light to exit the exit face while still providing significant improvements over prior LED light emissions. For example, light emitted from the exit surface of the LED may be emitted from the exit surface with a cone half angle of 10-60 degrees with approximately 79% efficiency (there is approximately a 21% efficiency loss due to fresnel losses for a silicon carbide substrate material of 2.73 index of refraction) with a desired intensity profile, exitance profile or other light output profile.

Fresnel losses (e.g. losses at the interface between two mediums such as at the exit face of an LED and air or other medium) occur when light traverses from a medium of higher index to a medium of lower index. Normal incident fresnel losses are described by the equation:

(N₁−N₂)²)/((N₁+N₂)²),

wherein N₁ and N₂ are the indices of refraction of the two mediums. As an example, for an LED having a silicon carbide substrate, N₁=2.73 (approximate IOR of silicon carbide), N₂=1 (approximate IOR of air), yielding Fresnel losses of approximately 21.5%. If the LED utilizes GaN in the quantum well region, Fresnel losses at the interface between the quantum well region (N₁=2.49) and the silicon carbide substrate (N₂=2.73) will be 0%. Fresnel losses at the exit face to air interface may be reduced or overcome with anti-reflective coatings.

The size of the exit face of an LED substrate can be selected to conserve radiance. The passage of light along an optic path, either within a single medium or from one medium to another, is governed by the law of Conservation of Radiance, also referred to as the Brightness Theorem, which is expressed by the Etendue equation:

$$\begin{matrix}Etendue Equation & \\ \frac{{Φ}_{1}}{{N}_{1}^{2} {A}_{1} {Ω}_{1}} = \frac{{Φ}_{2}}{{N}_{2}^{2} {A}_{2} {Ω}_{2}} & [ EQN . 1 ]\end{matrix}$$

Φ₁=light flux (lumens) of region 1
N₁=IOR of medium of region 1
A₁=area of entrance to region 1
Ω₁=solid angle (steradians) that fully contains the light of region 1
Φ₂=light flux (lumens) of region 2
N₂=IOR of medium of region 2
A₂=area of entrance to region 2
Ω₂=solid angle (steradians) that fully contains the light of region 2

The area of the exit face of a shaped substrate can be selected to conserve radiance of light entering the substrate from the quantum wells for a desired half angle. Consequently, light can be emitted in a desired half angle with high efficiency. This is unlike traditional LEDs that both emit light with a half angle that is undesirable for many applications, therefore requiring additional optical devices to shape the light; and, emit a significant percentage of light through the sidewalls because the exit face is not large enough to conserve radiance; while also suffering absorption losses due to the light never escaping the substrate.

Furthermore, the passage of light from a medium of one index of refraction to a medium of a different IOR is governed by Snell's Law. Snell's law defines the relationship between the angle of approach of a light ray as measured from the normal to the interface surface, and the angle of departure of that ray from the interface, as a function of the indices of refraction of both media.

Snell's Law: N₁ sin(Θ₁)=N₂ sin(Θ₂) [EQN. 2]

Θ₁=angle of incidence of ray approaching interface surface
N₁=IOR of medium 1
Θ₂=angle of refraction of ray departing interface surface
N₂=IOR of medium 2

In the case of the passage of light from a medium of higher IOR to a medium of lower IOR, the maximum angle at which a light ray may strike the interface surface between the media and still pass through the interface is called the critical angle. Fundamentally, light originating from the medium of higher IOR must approach the media interface at angles not exceeding the critical angle if the light is to pass through the interface and into the medium of lower IOR. For example, in an LED comprised of a substrate and a quantum well region, the substrate medium and the quantum well medium may form an interface that light generated by the quantum well regions traverses. Rays that approach at angles greater than the critical angle will be reflected back within the medium of higher IOR at the interface between the media and will not pass into the medium of lower IOR. This is referred to as total internal reflection (“TIR”).

In a typical GaN LED, the quantum well region has an IOR of approximately 2.49. When these layers are constructed on a sapphire substrate with an IOR of 1.77, the light that can be transmitted into the sapphire is inherently limited by the application of Snell's law and the Brightness Theorem. For LEDs with a substrate of silicon carbide, which may have an IOR of approximately 2.73, the quantum well region has a lower IOR (e.g. approximately 2.49) than the silicon carbide, and therefore Snell's law does not prohibit any of the generated light from passing into the silicon carbide.

In traditional LEDs, a significant portion of light encountering a substrate to air interface will be trapped in the substrate due to TIR. In some cases, a separate optical device (e.g. a solid plastic dome or lens) is used to increase the IOR of the medium into which light passes from the substrate, reducing TIR in the substrate.

These separate optical devices may still suffer from losses due to TIR, and the extraction efficiency of domes remains relatively low. Moreover, the use of a dome requires additional steps in manufacturing after the LED is formed. Embodiments of shaped substrate LEDs, on the other hand, can be shaped to minimize or eliminate light loss due to TIR at the exit face of the substrate.

According to one embodiment, the exit face of the substrate can be spaced from the interface with the quantum well region by a distance so that none of the rays with a direct transmission path to the exit face experience TIR at the exit face. Additionally, the sidewalls can be shaped to reflect rays encountering the sidewalls to the exit face with an angle of incidence at the exit face that is not greater than the critical angle, thus allowing all internally reflected rays to exit the exit face of the LED substrate as well.

FIG. 1A is a diagrammatic representation of one embodiment of a LED 20 including a substrate 10 and quantum well region 15 (that may comprise one or more layers or regions of doping). Quantum well region 15 includes a light emitting region 25, typically a compound semiconductor such as InGaN or AlInGaP or GaN, or other quantum well composition. Photons from quantum well region 15 may enter substrate 10 through interface 50.

LED 20 can be a wire bond, flip chip or other LED known or developed in the art. In FIG. 1A, both substrate 10 and quantum well region 15 form sidewall 60, sidewall 65 or other sidewalls. In other words, quantum well region 15 is shaped in conformance with substrate 10. In other embodiments, quantum well region 15 may not be shaped but, instead, have straight sidewalls. LED 20 further includes exit face 55 that may be substantially the same shape as, substantially parallel to and substantially rotationally aligned with interface 50 within the tolerance of the manufacturing process. The area of exit face 55 can be chosen to conserve brightness for a desired half angle according to the conservation of radiance (sometimes called the conservation of brightness) equation:

$$\frac{{Φ}_{2} {n}_{1}^{2} {A}_{1} {Ω}_{1}}{{Φ}_{1} {n}_{2}^{2} {Ω}_{2}} = {A}_{2} \qquad [ EQN . 1 ]$$

Φ₁=light flux traversing interface 50;
Φ₂=light flux exiting exit face 55, Φ₁=Φ₂ for conservation of brightness;
Ω₁=effective solid angle whereby light traverses interface 50;
Ω₂=effective solid angle whereby light leaves exit face 55;
A₁=area of interface 50;
A₂=area of exit face 55;
n₁=refractive index of material of substrate 10;
n₂=refractive index of substance external to substrate 10 (e.g. air or other medium).

A₂ represents the minimum surface area of exit face 55 such that light is conserved per the above equation.

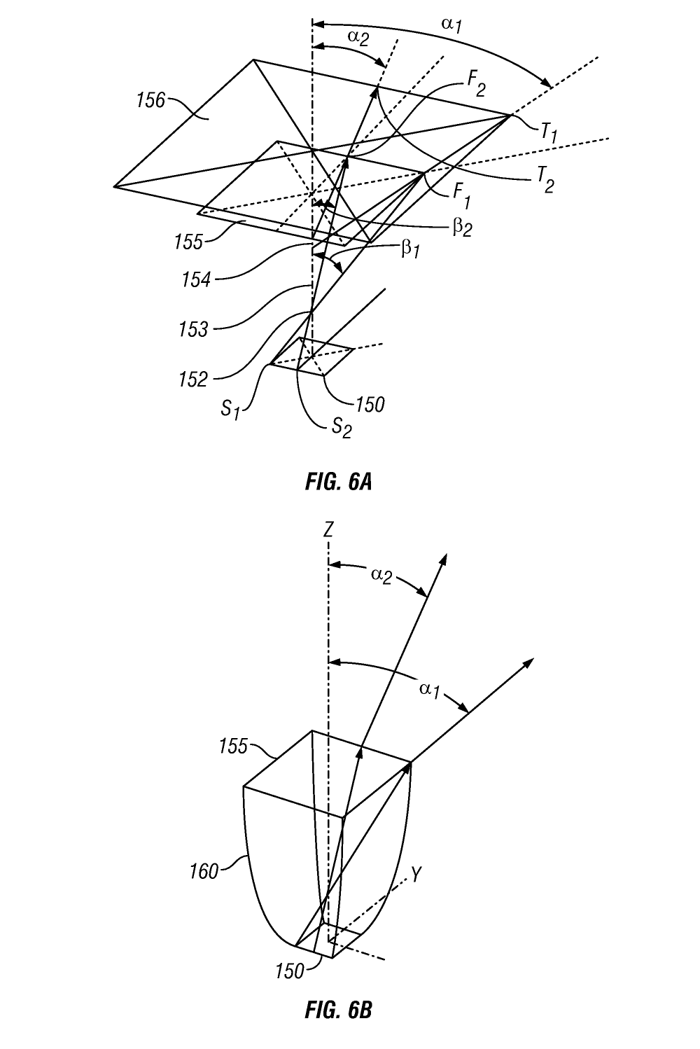

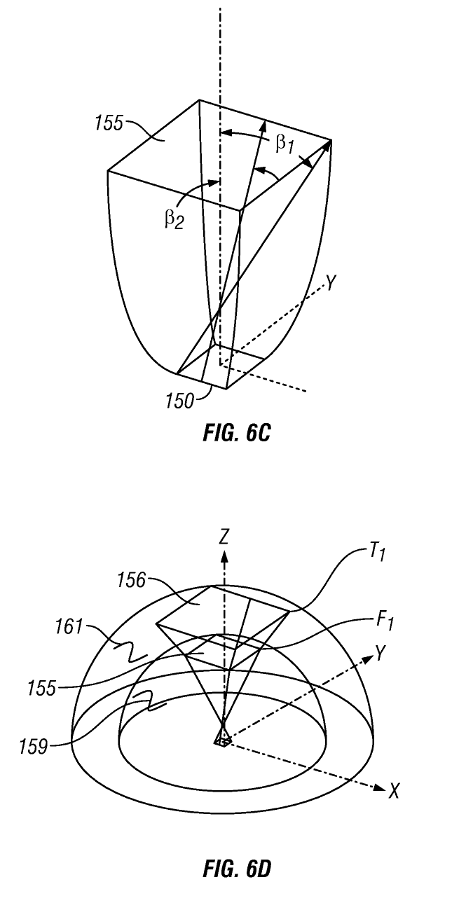

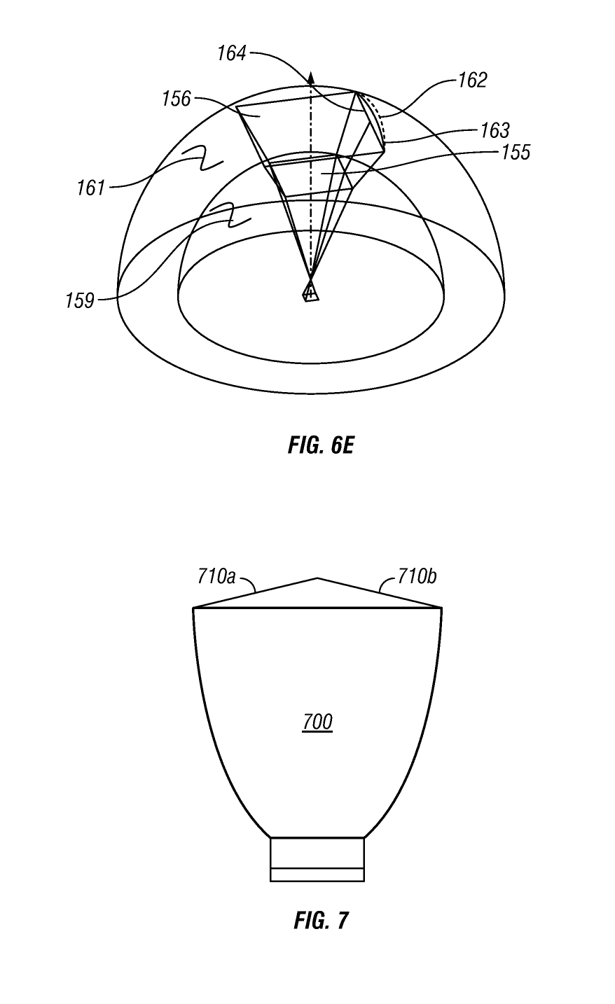

Assume, for example: quantum well region 15 forms a 1 mm square so that interface 50 has an area approximately 1 mm square, n₁=1.77, n₂=1, Ω₁=3, Ω₂=1, then A₂ must be at least 9.3987 mm² to conserve radiance (i.e. the minimum size of exit face 55 so that all of the light traversing interface 50 can be emitted from exit face 55 for a desired half angle). While in this example the effective solid angles are given, methods for determining Ω₁ and Ω₂ for a desired half angle are discussed below in conjunction with FIGS. 6A-6E. It should be noted that the square profile is a rectangular profile with sides of equal length.

A₂ according to EQN. 1 is the minimum possible size for a given output cone angle or Emission Half Angle to conserve radiance. Consequently, to conserve radiance, A₂ should be at least the size determined from EQN. 1, but may be larger. For example, A₂ may be made slightly larger to compensate for tolerances in the manufacturing process, errors in the size or shape of quantum well region 15 or other factors.

In the case where A₂ is made larger than the value determined by equation 1, flux will be conserved, but exitance (defined as flux per unit area) may be reduced from the maximum attainable value.

To reduce the area of the exit face, however, it may be desirable to make A₂ be as small as possible. For example, A₂ may be within 5% of the minimum area needed to conserve radiance. If some light power (luminous flux) may be sacrificed, A₂ can be smaller than the size dictated by the conservation of radiance. As one example, for one embodiment having a 1 mm by 1 mm square interface 50, exit face 55 can be 2.5 mm² to 5 mm² (e.g., 4.62 mm²). As another example, for an embodiment having 0.3 mm×0.3 mm interface 50, exit face 55 can be 0.2 mm² to 0.5 mm² (e.g., 0.42 mm²). It should be noted, however, the size ranges provided in the previous examples are provided by way of example only, and various embodiments can have a variety of sizes smaller than or greater than the example ranges. In one embodiment, however, A₂ is at least 70% of the value as determined by EQN. 1.

Furthermore, the shape of exit face 55 may be different than that of interface 50.

The distance between interface 50 and exit face 55 of substrate 10—referred to as the “height” herein, though the distance may extend in other directions than the vertical—may be selected to reduce or minimize TIR of light rays traveling directly from interface 50 to exit surface 55. TIR occurs when light is incident on the surface with an angle of incidence greater that critical angle, which is defined by:

n₁ sin(θ_{c})=n₂ sin(90) [EQN. 2]

where n₁=IOR of substrate 10;
n₂=IOR of the medium external to the exit face of substrate 10 (e.g., air or other substance); and
θ_{c}=the critical angle.

For example, if n₁=1.77 and n₂=1, then θ_{c}=34.4 degrees. Accordingly, the height of substrate 10 can be selected to limit the critical angle of rays incident on exit surface 55 to a range between normal to exit surface 55 and less than or equal to the critical angle.

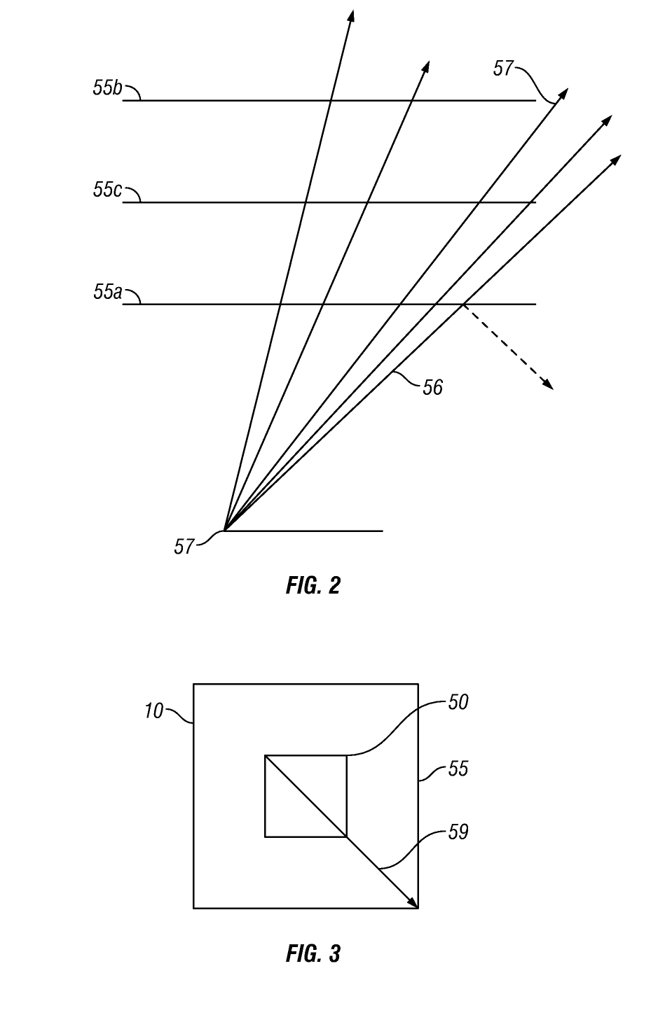

Referring to FIGS. 2 and 3, FIG. 2 is a diagrammatic representation of a set of rays traveling from point 57 incident on a surface 55 (represented as surfaces 55a, 55b and 55c at different distances from point 57). In the example of surface 55a, some rays (e.g., ray 56) are incident on surface 55a at greater than the critical angle, causing loss of light due to TIR. In the example of surface 55b, conversely, some rays that would be incident on surface 55b at the critical angle or somewhat less than the critical angle (e.g., ray 57) will instead be incident on the sidewalls. Preventing loss of these rays, if desired, can cause the complexity of the sidewall design to increase. Moreover, the additional height requires more room to accommodate the LED (i.e., because the LED is taller). Finally, in the case of surface 55c, rays at or less than the critical angle are incident on surface 55c while rays that would be greater than the critical angle on exit surface 55c instead are incident on the sidewalls. TIR or reflection can be used to direct the rays incident on the sidewalls to exit surface 55c as discussed below.

The limiting ray for selecting height, according to one embodiment, is the ray that travels the longest straight line distance from interface 50 to exit face 55 and is incident on exit face 55 at the critical angle. There may be more than one ray that can be selected as the limiting ray. In a square or rectangular configuration this is the ray that enters substrate 10 at a corner of interface 50 and travels in a straight line to the diagonally opposite corner of exit face 55 such that the ray would be incident on exit face 55 at the critical angle.

FIG. 3 provides a diagrammatic representation of a top view of substrate 10 and of limiting ray 59 for a square configuration. While in one embodiment the height of substrate 10 is selected to limit the critical angle of rays incident on exit face 55 to a range of between normal to exit face 55 and to less than or equal to the critical angle, other heights can be selected, though the use of other heights may decrease the efficiency of LED 20. In one embodiment, the distance between the interface between the other layers and the substrate and the exit face of the substrate may be within 5% of the minimum height that causes all rays with a straight transmission path from the interface to the exit face to have an angle of incidence on the exit face at less than or equal to the critical angle.

Returning to FIG. 1A, with selected boundary conditions of the size and shape of interface 50, size and shape of exit face 55, distance between interface 50 and exit face 55, the sidewalls (e.g., sidewall 60, sidewall 65 and other sidewalls) of substrate 10 can be shaped to direct light incident on the inner side of the sidewalls to exit face 55 to produce a desired light output profile (e.g., an intensity profile, exitance profile or other light output profile). While for most applications the desired intensity profile is uniform or close to uniform, other distribution profiles can be achieved by varying the height and shapes of the sidewalls.

Broadly speaking, the sidewall shapes are determined so that any ray incident on a sidewall is reflected to exit face 55 and is incident on exit face 55 at the critical angle or less (i.e., so that there is no loss due to internal reflection at exit face 55). This is shown in FIG. 1A by ray 70 that has angle of incidence 75 relative to sidewall 65 that is greater than θ_{c} so that ray 70 is reflected to exit face 55 and has an angle of incidence 80 that is less than or equal to θ_{c}. While, in one embodiment, the sidewalls are shaped so that all rays that encounter the inner surface of the sidewalls experience total internal reflection to exit face 55 and are incident on exit face 55 at the critical angle or less, other sidewall shapes that allow some loss can be used.

Turning to FIG. 1B, FIG. 1B is a diagrammatic representation of another embodiment of a LED 20. LED 20 comprises a substrate 10 and a quantum well region 15. Quantum well region 15 includes a light emitting region 25, typically a compound semiconductor such as InGaN or AlInGaP or AlGaN. Photons from quantum well region 15 may enter substrate 10 through interface 50. In FIG. 1B there may be more losses due to TIR in the quantum well region because the quantum well region is not shaped to appropriately direct light to interface 50 and/or exit face 55. While in the embodiments of FIGS. 1A and 1B, some sidewall shapes may not direct all the light generated by LED 20 out exit face 55, the portion of light not exiting exit face 55 will be emitted from sidewalls 65 and may be emitted near exit face 55, thus allowing for the light generated by LED 20 to be captured usefully.

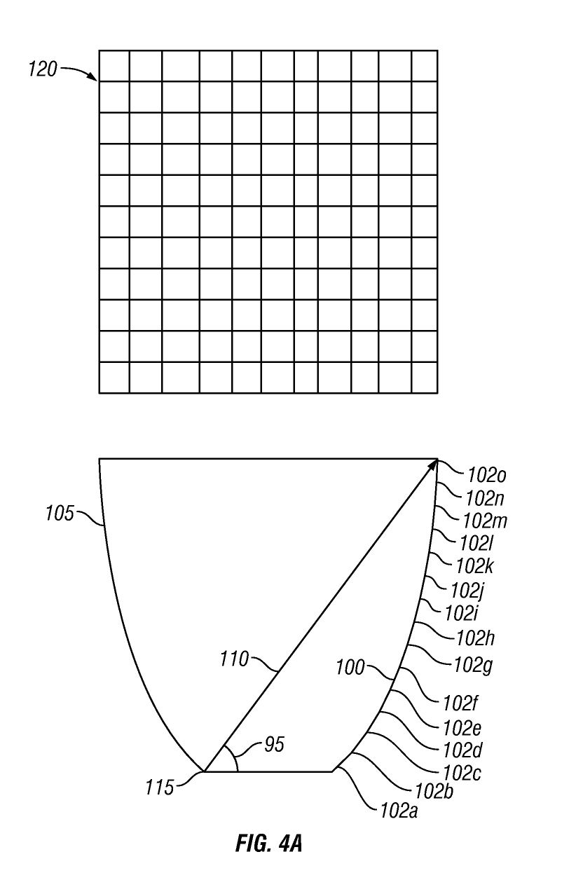

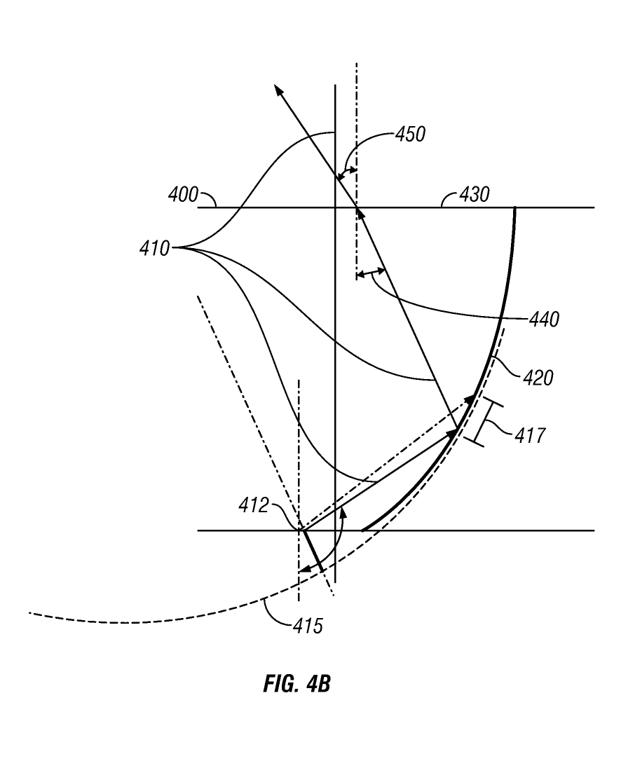

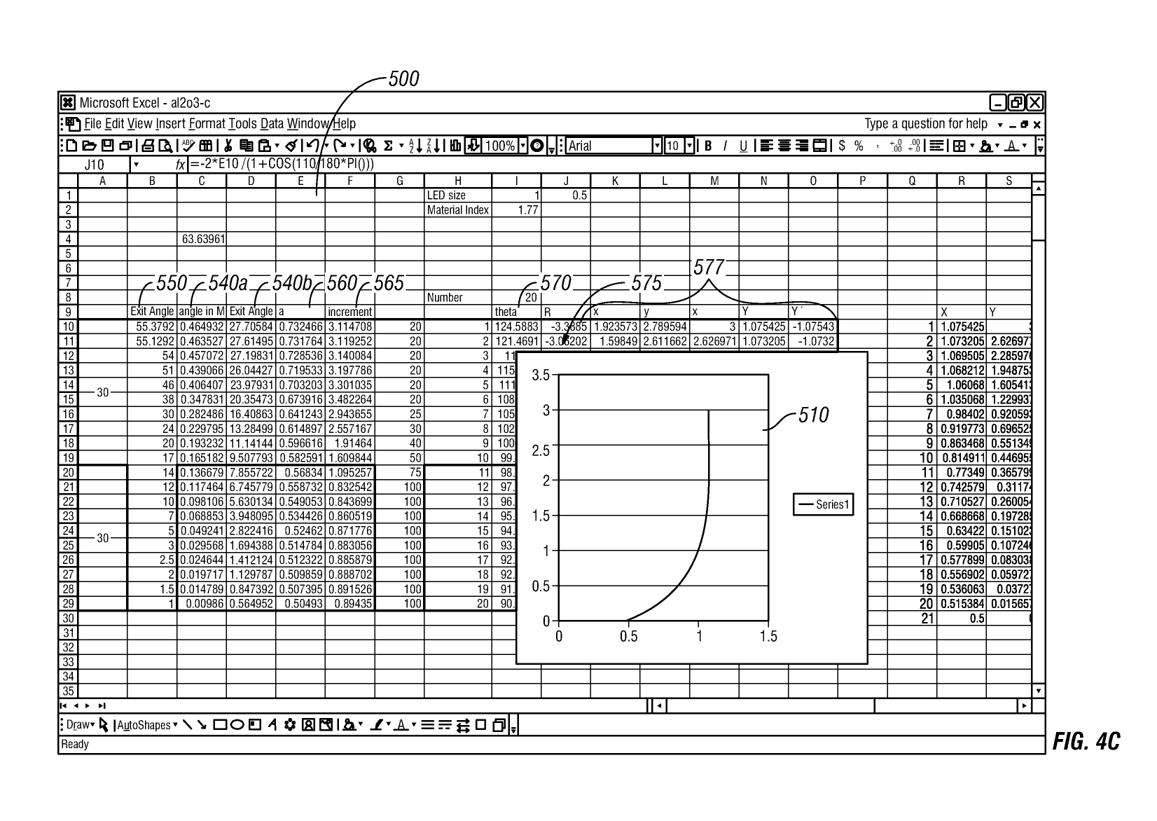

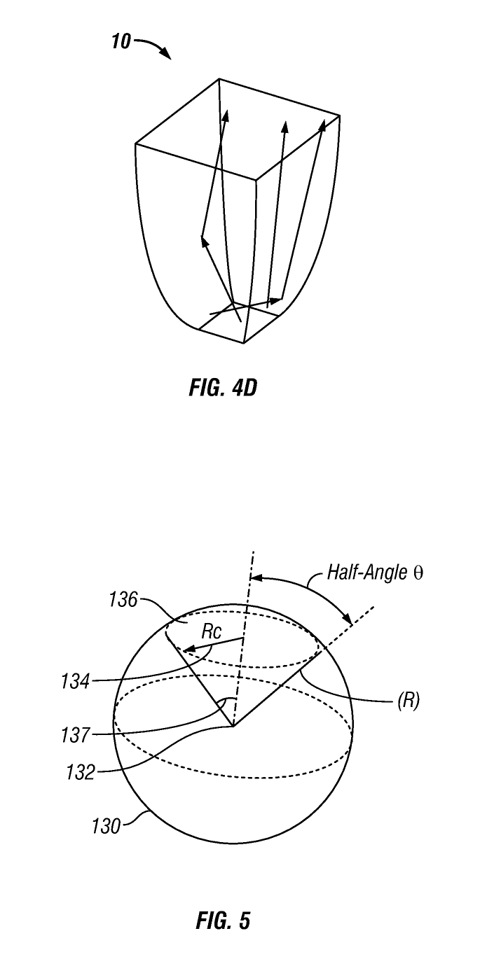

FIG. 4A is a diagrammatic representation of a cross-section of a model of a LED or a substrate of a LED for determining sidewall shapes. Sidewall shapes can be determined using computer-aided design. A model of the sidewall can be created in a computer-aided design package and simulations run to determine an appropriate sidewall shape.

According to one embodiment, each sidewall can be divided into n facets with each facet being a planar section. For example, sidewall 100 is made of fifteen planar facets 102a-102o rather than a continuous curve. The variables of each facet can be iteratively adjusted and the resulting distribution profiles analyzed until a satisfactory profile is achieved as described below. While the example of fifteen facets is used, each sidewall can be divided into any number of facets, including twenty or more facets. In another embodiment, the sidewall can be divided into three facets as described below.

Each facet can be analyzed with respect to reflecting a certain subset of rays within a substrate. This area of interest can be defined as an “angular subtense.” The angular subtense for a facet may be defined in terms of the angles of rays emanating from a predefined point. The point selected can be one that will give rays with the highest angles of incidence on the facet because such rays are the least likely to experience TIR at the facet.

In a substrate with a square shaped interface area, for example, this will be a point on the opposite edge of the interface.

According to one embodiment, for a selected A₁, A₂, and height, the maximum of angle 95 of any ray that will be incident on a given sidewall (e.g., sidewall 100) without being previously reflected by another sidewall can be determined. In this example, ray 110 emanating from point 115 establishes the maximum angle 95 for sidewall 100. If the maximum of angle 95 is 48 degrees and there are 15 facets for sidewall 100, each facet (assuming an even distribution of angular subtenses) will correspond to a 3.2 degree band of angle 95 (e.g., a first facet will be the area on which rays emanating from point 115 with an angle 95 of 0-3.2 degrees are incident, the second facet will be the area on which rays emanating at point 115 with an angle 95 of 3.2-6.4 degrees are incident, and so on).

For each facet, the exit angle, facet size, tilt angle, or other parameter of the facet can be set so that all rays incident on the facet experience TIR and are reflected to exit surface 55 such that they are incident on exit surface 55 with an angle of incidence of less than or equal to the critical angle. The sidewalls can also be shaped so that a ray viewed in a cross-sectional view only hits a side wall once. However, there may be additional reflection from a sidewall out of plane of the section. For a full 3D analysis, a ray that strikes a first sidewall near a corner, may then bounce over to a second side wall, adjacent to the first, and from there to the exit face. A curve fit or other numerical analysis may be performed to create a curved sidewall shape that best fits the desired facets. In FIG. 4A, for example, sidewall 105 is curved rather than a set of planar facets.

To optimize the variables for each facet, a simulated detector plane 120 can be established. Detector plane 120 can include x number of detectors to independently record incident power. A simulation of light passing through the substrate may be performed and the intensity and irradiance distributions as received by detector plane 120 analyzed. If the intensity and irradiance distributions are not satisfactory for a particular application, the angles and angular subtenses of the facets can be adjusted, a new curved surface generated and the simulation re-performed until a satisfactory intensity profile, exitance profile or other light output profile is reached. Additional detector planes can be analyzed to ensure that both near field and far field patterns are satisfactory. Alternatively, the simulation(s) can be performed using the facets rather than curved surfaces and the surface curves determined after a desired light output profile is reached. In yet another embodiment, the sidewalls can remain faceted and no curve be generated.

According to another embodiment, the sidewall shape can be selected based on multiple parabolas with each planer facet representing a linear approximation of a portion of a parabola. For example, FIG. 4B is a diagrammatic representation of a portion 400 of a LED. In FIG. 4B, a hypothetical ray 410 is depicted that emanates from the focus 412 of a parabola 415 and intersects sidewall 420 such that it is reflected off sidewall 420 due to TIR and traverses the substrate to intersect exit face 430 at an exit angle 440 that is less than the critical angle and exits the substrate into air or other medium. As can be seen from FIG. 4B, at the transition from the substrate to air, ray 410 bends as described by Snell's law. Since the tangent point of the sidewall is determined from a parabola and because the ray incident and reflected off the sidewall is in the same medium, the ray will be parallel to the optical axis of the parabola. Thus, light is projected with a half-angle 450. Angular subtenses defining the shape of sidewall 420 may be adjusted such that hypothetical ray 410 reflects off sidewall 420 such that ray 410 traverses exit face 430 with a desired exit angle 440 or projects light with a desired half angle 450.

In one embodiment, when fabricating a sidewall or calculating the angular substense of a sidewall, finer substenses may be used towards the base of the sidewall (i.e. nearer the quantum well region) because the effects of the substense are greater or more acute upon reflection near the base, and thus finer subtenses allow for a sidewall with better TIR properties, whereas further from the base, where the effects of the subtenses are less, the subtenses may be coarser. Thus, facets of a sidewall may be numerically greater towards the base of a shaped substrate LED. In one embodiment, a sidewall may have 20 or more facets, with finer facets at the base of the sidewall, wherein the facets approximate one or more subtenses.

A facet can be a linear approximation of a portion 417 of parabola 415. The parameters of parabola 415 can be adjusted until portion 417 achieves the desired goal of all rays incident on portion 417 reflecting to exit face 430 such that the rays have an exit angle 440 of less than the critical angle. Each facet can be formed from a parabola having different parameters. Thus, a facet for one angular subtense may be based on a parabola rather than an adjoining facet. A 20-facet sidewall, for example, may be based on 20 different parabolas.

FIG. 4C is a diagrammatic representation illustrating that the facets for a sidewall can be defined using a computer program such as Microsoft Excel (Microsoft and Excel are trademarks of Redmond, Wash.-based Microsoft Corporation). The graphing feature in Microsoft Excel can be used to create a graph, shown at 125, of a sidewall shape. The same general shape can be used for each sidewall or different shapes for different sidewalls. A shaped substrate with the specified sidewall shape (or with a curved sidewall shape based on the specified facets) can be analyzed in, for example, Zemax optical design program (Zemax is a trademark of Zemax Development Corporation of Bellevue, Wash.). A computer simulation can be conducted in Zemax to generate a ray trace and an intensity and irradiance distribution profile. If the resulting intensity and irradiance profile has an unsatisfactory distribution or the transmission efficiency of the shaped substrate is too low, the variables of the various facets can be adjusted and the simulations performed again. This process can be automated through the use of a computer program to automatically adjust facet variables.

More specifically, FIG. 4C depicts a spreadsheet 500 that can be utilized to design a sidewall shape as shown in graph 510 through the specification of angular subtenses. Projected half angle column 550 contains a plurality of angles that correspond to projected half angle 450 of FIG. 4B. Exit angle columns 540a (in radians) and 540b (in degrees) contain a plurality of exit angles corresponding to exit angle 440 of FIG. 4B. More particularly, all or a subset of the angles in column 540a may be angles that are less than the critical angle such that light rays intersecting the exit face at those angles traverse the exit face, exiting the substrate. Columns 540a and 540b may be utilized to develop parabola focus column 560, containing a plurality of foci defining different parabolas. Angular subtense column 565 contains a plurality of angles (in radians) that define the limits of an angular subtense that can be used in conjunction with parabola focus column 560 to define the shape of a sidewall such that a ray from the quantum well region reflects off the sidewall to exit the exit face at less than the critical angle. Using the values contained in parabola focus column 560 and angular subtense column 565, theta column 570 and radius column 575 can be developed wherein corresponding values in columns 570 and 575 correspond to points on a desired parabola for the angular subtense. In turn, theta column 570 and radius column 575 can be utilized to develop Cartesian coordinates for points on a sidewall (e.g. coordinate transformation columns 577) that approximate the parabola for the angular subtense.

For example, a user can specify the LED size (i.e., the area of the interface between the substrate and quantum well region) and the material index. Using the example of an LED having a size of 1, and an index of refraction 1.77, a row in screen 500 can be completed as follows. The user can specify an exit angle in air (assuming air is the medium in which the LED will operate) in column 550. In the example of the first row, the user has selected 55.3792 degrees. The exit angle in the substrate can be calculated as sin(55.3792/180*π)/1.77 or 0.4649323 radians, column 540a. Column 540b can be calculated as a sin(0.4649323)/π*180=27.2058407. The focus of the parabola can be calculated as 1(size)/2*(1+cos(π/2−27.2058407/180*π))=0.732466. Angular subtense column 565 can be calculated based on the number in the next column (representing the relative size of a particular facet) as (90−27.7058047)/20=3.114708. Theta column 570 can calculated using a selected number of facets (in this example 20). For example, in the first row theta is calculated as (90−27.7058407)+3,114708*20=124.5883. The radius of the parabola (column 575) for the first facet can be calculated as 2*0.732466/(1+cos(124.5883/180*π)). The contents of coordinate transformation columns 577 can be calculated as follows for the first row: x=−3.3885*cos(124.5883/180*π)=1.923573; y=−3.3885*sin(124.5883/180*π)=2.789594, X=1.923573*cos(27.7058407/180*π)+2.789594*sin(27.7058407/180*π); Y=2.789594*cos(27.7058407/180*π)−1.923573*sin(27.7058407/180*π)−1(size)/2=1.075452 and Y′=−Y. The X, Y coordinates can then be used as data point inputs for a shape fitting chart in Excel. For example graph 510 is based on the data points in the X and Y columns (with the Y column values used as x-axis coordinates and the X column values used as y-axis coordinates in graph 510). In addition to the X and Y values a starting value can be set (e.g., 0.5 and 0). The shape from graph 510 can be entered into an optical design package and simulations run. If a simulation is unsatisfactory, the user can adjust the values in spreadsheet 500 until a satisfactory profile is achieved.

In one embodiment, when a satisfactory light transmission efficiency and irradiance and intensity profiles are achieved, a LED with a substrate having the specified parameters can be produced. An example of such a LED is shown in FIG. 4D which provides a diagrammatic representation of one embodiment of a LED having a substrate with sidewalls shaped to cause TIR so that rays are reflected from the sidewalls to the exit surface.

The shape of each sidewall, in this embodiment, is a superposition of multiple contoured surfaces as defined by the various facets. While a curve fit may be performed for ease of manufacturability, other embodiments can retain faceted sidewalls. While in FIG. 4D, the area of the quantum well region is shown as being square or rectangular, this is by way of illustration and not limitation. For example, the shape of the area of the quantum well region can be any of a variety of shapes, e.g. circular, rectangular, triangular. Likewise, the shape of the exit face of a LED can be any of a variety of shapes, e.g. circular, rectangular, triangular.

Returning to FIGS. 1A and 1B, as described above with regard to FIGS. 1A and 1B, various boundary conditions, particularly the area of exit face 55 of substrate 10, are determined for substrate 10 so that light is conserved. The minimum area of exit face 55 can be determined from EQN. 1 above, which relies on various effective solid angles. Typically, the effective solid angle of light is determined based on equations derived from idealized sources that radiate as Lambertian emitters, but that are treated as points because the distances of interest are much greater than the size of the source. The observed Radiant Intensity (flux/steradian) of a Lambertian emitter varies with the angle to the normal of the source by the cosine of that angle. This occurs because although the radiance (flux/steradian/m²) remains the same in all directions, the effective area of the emitter decreases to zero as the observed angle increases to 90 degrees from normal. Integration of this effect over a full hemisphere results in a projected solid angle value equal to π steradians.

Turning to FIG. 5, assume a sphere 130 of given radius (R) surrounds point source 132 (in this example, point source 132 approximates a Lambertian source at a significant distance). The projected area of a hemisphere of the sphere is πR² and the projected area of the full sphere is 2πR². This model can be used to design a LED because an interface between a quantum well region and a substrate can be modeled as a Lambertian emitter such that from any point on a hypothetical hemisphere centered over the interface, a given point on the interface will have the same radiance. The area A₃ can be calculated as the flat, circular surface (e.g., surface 136) that is subtended by the beam solid angle of interest using a radius of the circle 134 (R_{c}) that is the distance from the normal ray to the intersection of the spherical surface. For a given half angle 137 of G of the beam, R_{c} is the product of R (the radius of the sphere) and the sine of the angle θ, such that

R_{c}=R*Sin(θ) [EQN. 3]

The area equals:

A₃=πR_{c}²=π(R*Sin(θ))² [EQN. 4A]

The area A₃ is the projected area of the solid angle as it intersects the sphere. The area A₃ is divided by the projected area of the hemisphere (Aₕ=πR²) and the quotient is multiplied by the projected solid angle of the full hemisphere (equal to π) to obtain the projected solid angle Ω, such that:

$$\begin{matrix}Ω = π ⋆ \{ \begin{matrix}projected area of \\ desired solid angle\end{matrix} \} / ( \begin{matrix}projected area \\ of hemisphere\end{matrix} ) & [ EQN . 4 B ] \\ Ω = ( π ) ⋆ [ \{ {π ( R ⋆ sin ( θ ) )}^{2} \} / ( π {R}^{2} ) ] & [ EQN . 4 C ] \\ = π ⋆ {Sin}^{2} ( θ ) & [ EQN . 5 ]\end{matrix}$$

For interface 50 of FIG. 1, for example, θ is 90 degrees, leading to a projected solid angle of π*Sin²(90)=π, and for the desired half angle of 30 degrees, the projected solid angle is π*Sin²(30)=π/4. Using these values for Ω₁ and Ω₂ for EQN. 1, A₂ can be determined for any half angle.

In the above example, the solid angle is determined using equations derived from a Lambertian source modeled as a point source. These equations do not consider the fact that light may enter a substrate from a quantum well region through an interface that may be square, rectangular, circular, oval or otherwise shaped. While the above-described method can give a good estimate of the solid angle, which can be later adjusted if necessary based on empirical or computer simulation testing, other methods of determining the effective solid angle can be used.

FIGS. 6A-6E describe another method for determining the effective solid angle for a substrate of an LED. FIG. 6A is a diagrammatic representation of one embodiment of an interface 150 and an exit face 155 of a shaped substrate 160 (shown in FIG. 6B) and a hypothetical target plane 156 onto which light is projected. FIG. 6A illustrates examples for a position of an effective source origin 152, central normal 153 and effective output origin 154. For purposes of further discussion, it is assumed that the center of interface 150 is at 0,0,0 in a Cartesian coordinate system. Target plane 156 represents the parameters of the resulting pattern (e.g., size and half angle used by other optics). According to one embodiment, the half angle at the diagonal (shown as α₁ in FIG. 6B) is the starting point. For example, if the desired light at target plane 156 has a maximum half angle of 30 degrees, α₁ for a square- or rectangular-faced substrate is 30 degrees. The half-angle within shaped substrate 160 (labeled β₁ and also shown in FIG. 6C) can then be determined according to:

n₂ Sin(α₁)=n₁ Sin(β₁) [EQN. 6]

where n₁ is the IOR of shaped substrate 160;
n₂ is the IOR of the material (typically air) into which the light is projected from shaped substrate 160;
α₁ is the half angle at the exit face in the medium external to the substrate (typically air);
β₁ is the desired half angle in the substrate.

For example, if the desired half-angle α₁ is 30 degrees, and a shaped substrate having an IOR of 1.77 is projecting into air having an IOR of 1, then β₁=16.41 degrees. A similar calculation can be performed for a ray projecting from a point on the long and short sides of entrance face 150. For example, as shown in FIGS. 6B and 6C, α₂ and β₂ can be determined for a ray traveling from the center of one edge on interface 150 to the center of the opposite edge of exit face 155. (The critical angle is the same at 16.41, but β₁ is not the same as β₂. β₂ is determined by the geometry of the sides and the height of the shaped substrate.)

Using the angles calculated, the location of an effective point source can be determined. For a square interface 150, of length l₁, the effective point source will be located X=0, Y=0 and

$${Z}_{eps} = \frac{{l}_{1}}{\sqrt{2} ⋆ tan ( {β}_{1} )} \qquad [ EQN . 7 ]$$

Where Zₑₚₛ is the distance the effective point source is displaced from entrance face 150 of shaped substrate 160.

The X, Y and Z distances from the effective point source to points F₁ and F₂ can be calculated assuming F₁ intersects a sphere of unity radius according to:

X_{F1}=cos(ψ₁)sin(β₁) [EQN. 8]

Y_{F1}=sin(ψ₁)sin(β₁) [EQN. 9]

Z_{F1}=cos(β₁) [EQN. 10]

X_{F2}=0 [EQN. 11]

Y_{F2}=cos(ψ₂)*sin(β₁) [EQN. 12]

Z_{F2}=cos(β₁) [EQN. 13]

where ψ₁ the angle of the diagonal ray in the X-Y plane (45 degrees for a square) and where ψ₂=90 degrees for a ray projecting from the middle of a side parallel to the X axis as shown in FIG. 6C. As shown in FIG. 6A, because 156 intersects the spherical surface at four points and the magnitude of angle β₂ is less than the magnitude of critical angle β₁, the values for point F₂ are calculated based on the projection of a diagonal with an angle β₁ onto the plane of the side ray. A similar methodology based on the geometries previously calculated can be used to determine other points (e.g., for example, the location of points T₁ and T₂ can be determined based on the location of points F₁ and F₂ and the desired half angle of light at target plane 156.)

FIG. 6D illustrates the diagonal rays and one ray from the short side projected onto a sphere 159 for exit face 155 and sphere 161 for target plane 156. For exit face 155, the projection of the intersection of the edge rays at the sphere 159 onto the plane of the exit face 155, forms elliptical segments. Likewise, the projection of the refracted exit rays at the edge of the target face intersects the sphere 161. FIG. 6E, for example, points out the circular intersection of the rays lying in the plane formed by the edge 163 of target face 156 intersecting sphere 161 (shown at 162), and the projection of that intersection onto the target plane 156 (shown at 164). By calculating the area of each of the elliptical segments surrounding the square of the target face and adding that to the area of the target face, we find the total projected area of the target face. The effective solid angle can be determined for the target plane using EQN. 4B Similarly, by using sphere 159 and the elliptical segments formed thereon by rays, the effective solid angle for the LED can be determined. For example, the total projected area is determined as described above and inserted as “projected area of desired solid angle” in EQN. 4B.

As one illustrative example, using the above method to project light with a half-angle of 30 degrees using a LED having a substrate with a square shaped interface and exit face yields an effective solid angle of 0.552 steradians to the target in air. By contrast, the use of the traditional circular projected area with a 30 degree half angle projection specification would yield an effective solid angle of 0.785 steradians. When these values are then used in EQN. 1, for given IORs and flux, the traditional (circular) calculation yields a required exit area that is undersized by about 30%. If one were to design a system using this approach, the applicable physics (i.e. the conservation of radiance) would reduce the light output by 30% over the optimum design. Conversely, using the corrected effective solid angle described above calculates an exit face area that will produce 42% more light output than is achievable with the circular calculation.

Although particular methods of determining the effective solid angle for a LED are described above, any method known or developed in the art can be used. Alternatively, the minimum surface area to conserve light can be determined empirically. Moreover, while the minimum surface area calculations above assume light is entering the substrate across the entire surface of the interface between the non-substrate layer and the substrate, in physical devices, light may not enter the substrate in an even distribution across the entire surface of the interface. The calculations of the minimum area of the exit face can be adjusted to account for the actual distribution of light traversing the interface, rather than being based entirely on the size of the area of the interface. In one embodiment, the actual area of the interface through which light enters the substrate can be used as A₁.

Embodiments of LEDs can project light into a desired cone angle of 10-60 degrees with a theoretical efficiency of up to 89% (meaning that 89% of the light entering the substrate is emitted in the desired half-angles with 11% fresnel loss) depending on substrate material and Fresnel losses. The efficiency can be 100% without fresnel losses. Even at only 70% efficiency, embodiments of LEDs provide greater efficiency than other LED technologies, while also allowing for uniform or near uniform intensity distributions at both near and far fields.

Fresnel losses at the substrate to air (or other medium) interface can be overcome by the application of anti-reflective coatings to the exit face of the substrate. Anti-reflective coatings that can be used are any that would be known to one of ordinary skill in the art and include single layer MgO or MgF, multilayer coating or other anti-reflective coatings. Through the utilization of anti-reflective coatings, Fresnel losses can be reduced or eliminated, increasing the light output efficiency of a LED.

An embodiment of a LED may have more than one exit face. For example, a shaped substrate may allow substantially all the light generated by the LED to exit the LED, but through more than a single exit face. FIG. 7 is a diagrammatic representation of an example of a LED 700 with more than one exit face. In FIG. 7, exit faces 710a and 710b of LED 700 are shown. A LED having more than one exit face might emit light into a solid angle greater than a hemisphere. To maximize the light exiting the exit faces, the sidewalls of a substrate with more than a single exit face may have multiple curved or faceted surfaces.

For a LED with two or more exit faces, it is possible for the solid angle of emission of the LED to be greater than a hemisphere (and the projected solid angle to be greater than pi). An example of this would be if instead of a single planar exit face, the LED had a four sided pyramidal set of exit faces. If the sidewalls of the substrate of the LED are shaped to direct light entering the substrate through the interface to one of the four exit faces so as to strike the exit face at an angle not greater than the critical angle, then all the light entering the substrate may exit the LED through one of the four exit faces.

Since the faces of the pyramid are not in a plane, but rather are at angles to each other, any ray that strikes an exit face at the critical angle to that exit face will refract to an exit angle of 90 degrees. The total solid angular space defined this way would then be a function of the angular relationship of the four exit faces. To satisfy the etendue equation, the four exit faces in this example would have to have a total surface area at least equal to the calculated value using the effective solid angle for that construction.

This multi-exit face construction may still be constructed in such a way as to conserve radiance. That is, by making the total projected exit face area equal to the calculated value, and by designing the sidewalls to provide uniform distribution of the light to each portion of the exit faces, radiance can be conserved. If the exit faces are made larger than the required value, then light entering the substrate may exit through the exit faces, with a corresponding reduction in luminous intensity.

A further embodiment of a shaped substrate with multiple exit faces is one in which the sidewalls of the shaped substrate are themselves exit faces. Depending on a point of entrance of a given light ray, it may strike a given sidewall at an angle not greater than the critical angle, and pass through that sidewall, or it may strike at an angle greater than the critical angle and be internally reflected to another face or sidewall.

If the sidewall exit faces and sidewalls are designed such that any ray entering the substrate from any point on the interface passes through a sidewall exit face, then all of the light entering the substrate will exit the substrate.

Shaped substrate LEDs with multiple exit faces may be appropriate for use in general lighting applications where broad area emission is desired. Such LEDs may be used in conjunction with additional lens or reflector elements that will direct light produced by the LED into a smaller solid angle.

The potential benefit of a shaped substrate with multiple exit faces or in which sidewalls act as exit faces is that the LED may have a smaller volume or may have a shape that is more readily manufactured—such as planar faces instead of curved surfaces.

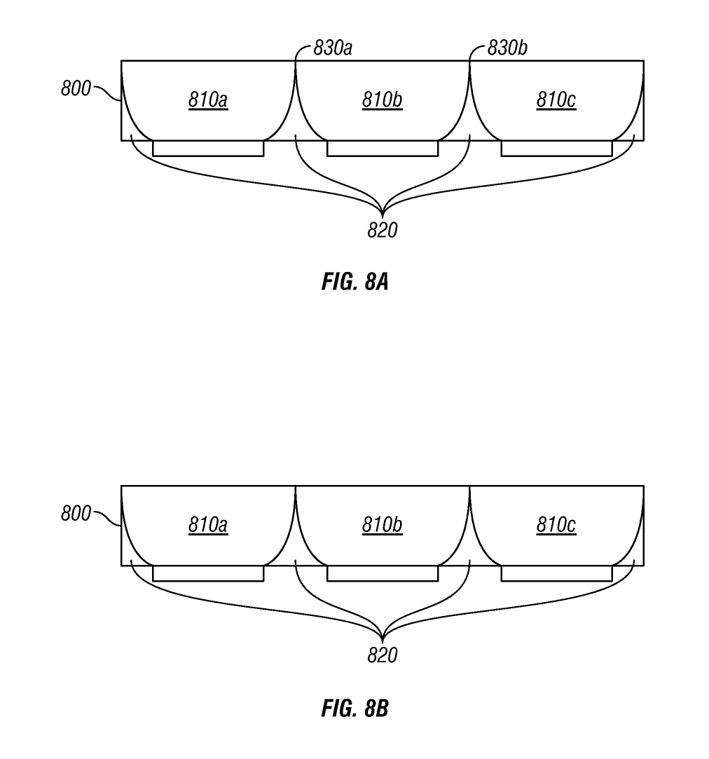

LEDs can be arranged in an array of LEDs. An array of LEDs can be used to produce a desired amount of light and a desired light pattern. For example, LEDs may be arranged in a square or other shape. Using an array of LEDs to produce the desired amount of light may be more efficient or may consume less space than using a single LED. An array of LEDs can be formed during manufacture. For example, an array of LEDs can be formed from the same wafer. In FIG. 8A, LED array 800 comprises LEDs 810a-810c that are formed from the same wafer. Wafer material 820 is removed to form LEDs 810a-810c. LED 810a remains attached to LED 810b at point 830a. Likewise, LED 810b remains attached to LED 810c at point 830b. Thus, through the selective removal of substrate material, arrays of LEDs may be formed. FIG. 8 represents one method of forming arrays of LEDs and is illustrative and not limiting: other methods for forming arrays of LEDs as would be known to one skilled in the art are within the scope of the invention.

One advantage of using an array of LEDs is that the shaped substrates of the multiple LEDs in the array may be thinner than the shaped substrate for a single LED having the same amount of light output. Additionally, an array of smaller LEDs may be more efficient than a single LED; that is, an array of smaller LEDs that consume a certain amount of input power may produce more light than a single large LED of the same exit face size and input power.

One or more methods may be used to shape or form an LED or the substrate of an LED (or other optical device). The methods of shaping a substrate as described below are exemplary and comprise a subset of the numerous methods available. The methods described below and other methods used in the LED or optics industries may be used to produce LEDs. The methods can be used on various substrate materials including sapphire, silicon carbide, glass, or other substrate materials.

Prior to shaping a substrate material, the wafer or die including the substrate material can be prepared for shaping to provide one or more protective coatings or support layers. Generally, preparing the die for shaping can include mounting the substrate to a support structure that can act to hold the various optical devices together once formed, provide structural support during manufacturing and/or act as sacrificial layer that can be damaged during manufacture. The support structure can be made on any suitable material, which can depend on the shaping method used. Examples of support structures include glass, epoxy, sapphire, silicone or other material layer bonded to the substrate with epoxy or other adhesive materials. Examples of adhesives include, but are not limited to, Valtron AD4010-A/AD4015-B Heat Release Epoxy System (MP4010A/1015B-50) by Valtech Corporation of Sanatoga, Pa., Liofol UR 9640 by Henkel Corporation of Rocky Hill, Conn. or other adhesive. The addition of a metalized layer to either the substrate material or support structure can improve adhesion strength. For example, a 1 micron thick coating of evaporated Ti may be applied to either the substrate material or support structure to promote adhesion. Other metal layers include, but are not limited to, Titanium-Tungsten (TiW) or other layer of material that can promote adhesion.

Preparation can also include adding one or more layers of protective material to protect any metal or electric layers from damage by abrasives, chemicals, or tools. The protective layer can be selected so that the shaping process can shape the substrate material through the protective layer. According to one embodiment, the protective layer can be a resilient thermoplastic that will adhere to the outermost layer of the wafer. The material of the protective layer can be chosen based on the manufacturing methods to be employed, time constraints, and other factors. For example, a relatively tacky protective layer may be suitable for a wire saw shaping method, but may gum up an ultrasonic shaping tool. Examples of materials that can be used as protective layer include Cookson Staystik 393 bonding adhesive and other thermoplastics. The thickness of the protective layer can depend on material used in the protective layer and manufacturing process parameters. In other embodiments, the wafer can be prepared in other manners or be left unprepared.

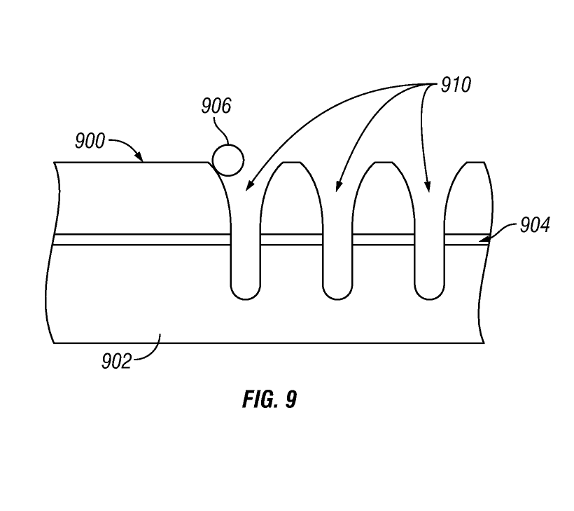

According to one embodiment, a wire saw can be used to cut the substrate material. FIG. 9 is a diagrammatic representation of one embodiment of cutting a wafer 900 used for LEDs. In this example, wafer 900 is mounted to mounting block 902, which can be cut in addition to wafer 900 allowing wafer 900 to be cut all the way through. Thus, mounting block 902 can act as both a support structure and a sacrificial layer. According to one embodiment, mounting block 902 can be an epoxy, wax or other material that is preferably low cost and stable under cutting. Adhesive layer 904 can be any suitable adhesive, and in particular embodiments can be one that allows the shaped devices to be cleanly removed from the mounting block after cutting or other processing. According to one embodiment, the adhesive can be an epoxy such as the epoxy provided in Valtron AD4010-A/AD4015-B Heat Release Epoxy System (MP4010A/1015B-50) by Valtech Corporation of Sanatoga, Pa. While the substrate layer of wafer 900 is shown, wafer 900 and the wafers depicted for other methods can include the light emitting layers and electrical layers as well.

An abrasive cutting wire 906 is used to cut wafer 900 in the desired shape. By way of example, but not limitation, an abrasive cutting wire 906 of 155 microns to 250 microns in diameter with diamond particles of approximately 20 microns can be used. Those of ordinary skill in the art would understand, however, that a variety of abrasive cutting wires with various diameters, abrasive particle types, abrasive particle sizes or other features can be used to achieve a desired sidewall shape.

In operation, abrasive wire 906 and wafer 900 can be moved relative to each other along multiple axes. For example, abrasive wire 906 can be lowered in a straight vertical path while wafer 900 is moved horizontally. If the vertical speed of wire 906 remains constant, the horizontal speed of wafer 900 can be continuously adjusted to achieve the desired shape. Alternatively, the speed of wafer 900 can remain constant for short periods of time to create multiple flat facets on the sidewall. In yet another embodiment, the horizontal speed can remain constant while the vertical speed of wire 906 is adjusted to create a curved, faceted or other sidewall shape. In yet another embodiment, the speed of both wire 906 and wafer 900 can be adjusted. While, in the foregoing embodiments, the relative motion of wire 906 and wafer 900 is achieved by moving both wire 906 and wafer 900, other embodiments can include moving wire 906 and/or wafer 900 both horizontally and vertically to create the desired shape. When a set of channels 910 has been cut in one direction, wafer 900 can be rotated a select number of degrees (90 degrees in the case of a square or rectangular faced LED or other degrees of rotation for other shapes such as hexagonal shaped LEDs) and the cutting process repeated until all the sidewalls of devices made from the wafer are shaped.

A wire saw inherently produces low contact forces on the substrate and the cutting is accomplished with a low mass wire. Some advantages of using a wire saw are: (i) the shape can be programmably generated, thus eliminating any fixed tooling costs for a specific shape, and the associated lead times for obtaining that tooling; (ii) the shape can be quickly modified in response to different design conditions; (iii) programmed path can be changed to better match the designed shape as process conditions change; (iv) the wafer can be mounted, as with an epoxy adhesive, onto a sacrificial block allowing the shaped cut to be made fully through the wafer in a single operation; (v) the wafer can then be fully polished on all the sidewalls while still in the original array. As an additional advantage, shapes having curves with undercut surfaces as viewed from the top can be produced by this method.

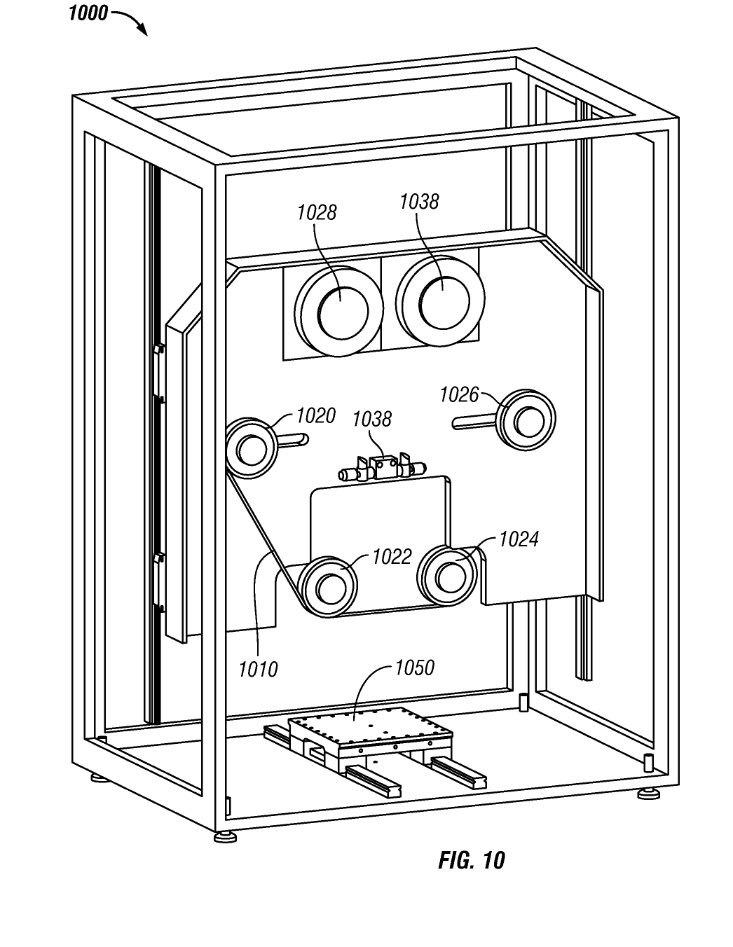

According to one embodiment, a wire cutting system can include a wire slicing machine and a motion control system that coordinates the cutting rate into the wafer with the sideways displacement of the wafer or wire so that a given shaped cut can be made. FIG. 10 is a diagrammatic representation of a specific example of a wire cutting machine 1000 to cut shaped substrates. It should be understood that the cutting machine described is provided by way of example and not limitation and that any suitable wire cutting system can be used. According to one embodiment, the cutting machine can be a modified RTS440 by Diamond Wire Technologies, LLC of Colorado Springs, Co. The components of cutting machine 1000 can be made of any suitable material. According to various embodiments, materials that resist corrosion such as anodized aluminum are used. Cutting machine 1000 can include a cutting wire that is spooled. Only a portion of the path of cutting wire 1010 is shown, however cutting wire 1010 can run through pulleys 1020, 1022, 1024, 1026 from reel 1028 to reel 1030 in either direction. The various pulleys can be adjusted to tension the wire 1010. Cutting machine 1000 can produce wire speeds up to 3000 feet per minute and has a capacity of 10,000 feet, though other speeds and capacities can be used. Cutting machine 1000 can also include a cooling system 1038. Cooling system 1038 can use any suitable coolant. In the example of the base cutting machine, cooling system 1038 can produce up 5 gpm of water based coolant using a compressed air pump. Cutting wire 1010, pulleys 1020, 1022, 1024, 1026 and reels 1028 and 1030 can be mounted to a yoke 1040 that translates in vertical direction (along the z-axis for purposes of this application). Translation is controlled by a stepper motor. Various pulleys can be mounted on a rocker mechanism (not shown) which can programmably tilt the wire. While only a single cutting wire is shown, cutting machine 1000 can support multiple cutting wires.

In one embodiment, cutting machine 1000 includes a platform 1050 that is movable by a stepper motor along an axis (referred to as the x-axis for purposes of this application). Movement can be controlled by an x-axis stepper motor that has a desired resolution. In one embodiment, the stepper motor has an axis resolution of 0.0005 inches and a precision of 0.0001 inches. Other embodiments can utilize linear actuators, brushless DC motors or other mechanism to translate the wafer or cutting wire relative to each other. Furthermore, in other embodiments a wire cutting machine can be configured so that the wire moves relative to the wafer along the x-axis.

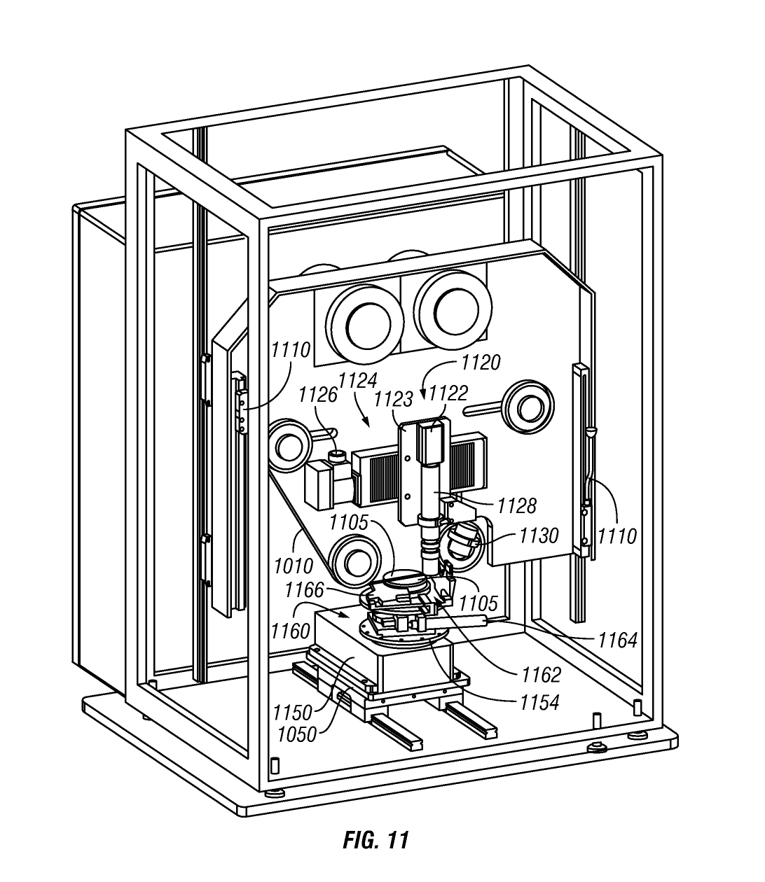

FIG. 11 is a diagrammatic representation of one embodiment of modified cutting machine 1000 for cutting a work piece 1105. Cutting machine 1000 can to include one or more z-axis encoders 1110 (two are shown in FIG. 11). The z-axis encoders allow an accurate determination of the z-axis position of yoke 1040. While encoders are used in this example, other systems can be used for position determination such as ultrasonic sensors, infrared sensors or other systems that can be used to provide accurate measurements of position. One example of an encoder is an RSF Linear encoder with 270 mm travel, end mounted extension with 0.1 micron resolution, part number BK71202AC016 from RSF Electronics, Inc. of Gold Tailings, Conn. Although not shown, a similar encoder, or other encoder can be added to the allow position determination of the platform 1050 along the x-axis.

According to one embodiment, the wire cutting machine can include cameras, sensors or other devices for determining the position of the cutting wire relative to the wafer.

In the example of FIG. 11, cutting machine 1000 can include a camera system 1120 having a camera 1122 that is translatable along one or more axes. A camera mount 1123 can be coupled to an actuator or other movement system 1124. According to an embodiment, movement system 1124 can include a motor 1126 to move camera mount 1123 through a drive shaft, linkage or other mechanism. An encoder (not shown) can be used to determine the y-axis position of camera mount 1123. Movement system 1124, according to one embodiment, can be liquid tight to prevent slurry, coolant or other liquids in cutting machine 1000 from damaging movement system 1124. Camera 1122 can include a tube 1128 to limit the field of vision of camera 1124. Any number of lenses, filters or other optical devices can be included in tube 1128. A light source 1130 can provide illumination for camera 1122.

Light source 1130 can be mounted to camera mount 1123 to move with camera 1122. In an embodiment, camera 1122 is within 2 inches of the centerline of cutting wire 1010.

However, camera 1122 can be placed in any suitable location that is closer to or further from the centerline. According to one embodiment, camera 1122 can provide images with a resolution of 1 micron per pixel or better and provide image sizes of at least 800×600 pixels.

According to one embodiment, motor 1126 and y-axis encoder can be included in the Aerotech ATS100 Series (100 mm stage with BMS brushless servo motor), Part No. ATS100-100 by Aerotech, Inc. of Forest Lake, Minn., camera 1122 can be a Basler ½, C-Mount 1392×1040, 18.7 fps, Mono, CCD from Basler Inc. of Exton, Pa., tube 1128 can be a Mitutoyo to C-Mount 152.5 mm extension tube, the lens can be a Mitutoyo Telecentric Objective 10× Lens, light source 1130 can be an Advanced Illumination, SL2420 Spotlight, Bright Field, Blu 470 nm 24V-XL, from Advanced Illumination, Inc. of Rochester, Vt. Camera 1122 can be mounted to camera mount 1123 with a Basler Tripod Mount for A630, A640 Series Cameras, Aluminum type. Motor 1126 can be controlled by an Aerotech Ensemble Motion Controller (part number MP10 from Aerotech, Inc) and/or an Aerotech Ensemble Motion Controller with I/O expansion board (part number MP10-IO). Camera system 1120 can allow the center of the lens field of view to travel at least 2 inches with a straightness of motion within 5 microns over two inches.

A rotational stage 1150 can be coupled to platform 1050 to allow rotation of work piece 1105 about the z-axis. According to one embodiment, rotational stage is centered on platform 1050 within plus or minus 5 mm. Rotational stage 1150 can, according to various embodiments, have a repeatability of plus or minus 5 arc seconds. In one embodiment, rotation stage 1150 provides a liquid tight enclosure 1152 for a rotary motor (referred to as the theta-z motor) and a rotary encoder. The rotary motor rotates turntable 1154. According to one embodiment, rotation stage 1150 can be a submersible 5 inch rotary stage, part number RMS-5-11 by Newmark Systems of Mission Viejo, Calif. that includes an encoder.

A tip/tilt stage 1160 can be mounted to turn table 1154. Tip/tilt stage 1160 can include servos and pivots to adjust the angle of the work platform 1162 relative the horizontal about two-axis. While only servo 1164 is illustrated, tip/tilt stage 1160 can include additional servos to adjust work platform 1162. A clamp 1166 can close to hold work piece 1105 in place. In other embodiments, a vacuum, fasteners, adhesive or other mechanism can be used to hold work piece 1105 in place. As discussed above work piece 1105 can include a wafer that can be coupled to a sacrificial layer (referred to as a dolly, below).

During calibration, a human or robotic device can place work piece 1105 on work platform 1162 and close clamp 1166. Platform 1050, rotary stage 1150 and tip/tilt stage 1160 can align the wafer for cutting. According to one embodiment this can be achieved using information from camera 1122. The wafer can include markings or fiducials that can be registered with camera 1122 either by a human user viewing images from camera 1122 or a program processing image data from camera 1122. The fiducial marks can have any suitable configuration. By way of example, but not limitation, the marks can be crosshairs with a line width of about 10 microns and length of about 100 microns, or lines with a specified lengths (for example several millimeters). Marks can be placed proximate to the ends of a particular channel to be cut by wire 1010.

According to one embodiment, platform 1050 is moved along the x-axis and camera 1122 along the y-axis to bring a first fiducial mark into the field of view of camera 1122 to align the fiducial mark in the camera (e.g., by centering the mark, aligning the mark with crosshairs or by other method). Work platform 1162 can be adjusted to focus the mark. Platform 1050 and rotary stage 1150 can be adjusted as needed to align a second fiducial with camera 1122. Platform 1050 and rotary stage 1150 can be iteratively adjusted until full travel from the first fiducial to the second fiducial can be accomplished without rotary adjustment. Additionally, tip/tilt stage 1160 can be adjusted so that both marks are in focus. Alignment can be achieved with the assistance of an operator and/or image processing programs.

With the wafer in proper alignment, platform 1050 can be moved a selected amount and a test cut performed using defined parameters. The test cut is nominally in the direction of the y-axis. The wafer can be removed and examined with instruments such as a toolmakers' scope or other instruments. The angularity and offset of the cut between the first and second fiducials can be measured.

These values provide offset data that can be used to calibrate the wire position relative to the camera position. In another embodiment, after the first cut is made, wafer 1190 can be rotated by rotary stage 1150 what should be 90 degrees. The second cut can also be measured to calibrate rotary stage 1150 so that rotary stage 1150 does indeed rotate 90 degrees (within its tolerances). According to an embodiment, calibration can be performed to ensure the streets of the wafer are parallel to the axis of the cutting wire within ±2 micron from one edge of the wafer to the opposite edge, at/near the wafer centerline.

In one embodiment, the wafer can be cut multiple times parallel to a first axis and then rotated for cuts parallel to the other axis. During cutting, the motion of yoke 1040 and platform 1050 can be controlled so that wire 1010 cuts the wafer in a desired shape. The speed of wire 1010 and other cutting parameters can be selected to reduce the force on wire 1010 to minimize bowing.

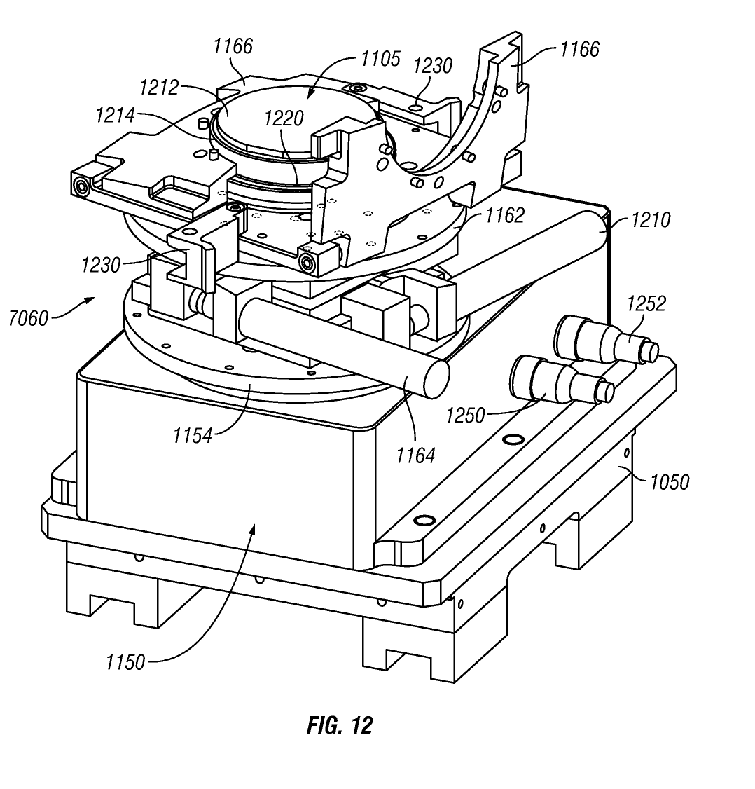

FIG. 12 is a diagrammatic representation of a portion of cutting machine 1000 illustrating platform 1050, rotation stage 1150 and tip/tilt stage 1160, including servos 1164 and 1210 to tip/tilt work platform 1162. Servos 1164 and 1210 can be, for example, DC servo motors with encoders. Tip/tilt stage 1160 includes, for example part number M-044 D01 from Physik Instrumente L.P., of Auburn Mass., which provides a tip/tilt stage up to work platform 1162. The tip/tilt stage can be controlled by Mercury-DC Mike controller (part number C-863.10) from Physik Instrumente L.P. In the embodiment of FIG. 12, work piece 1105 can include wafer 1212 and dolly 1214. Work piece 1105 can include a flange 1220 that can be captured by clamp 1166. When clamp 1166 is closed, arms 1230 can be moved to capture corresponding features of clamp 1166 to secure clamp 1166. When clamp 1166 is closed rubber pads on the underside can assert pressure on flange 1220 to securely hold dolly 1214. FIG. 12 also illustrates ports 1250 and 1252 for electrical connections to the rotary stage motor and encoder.

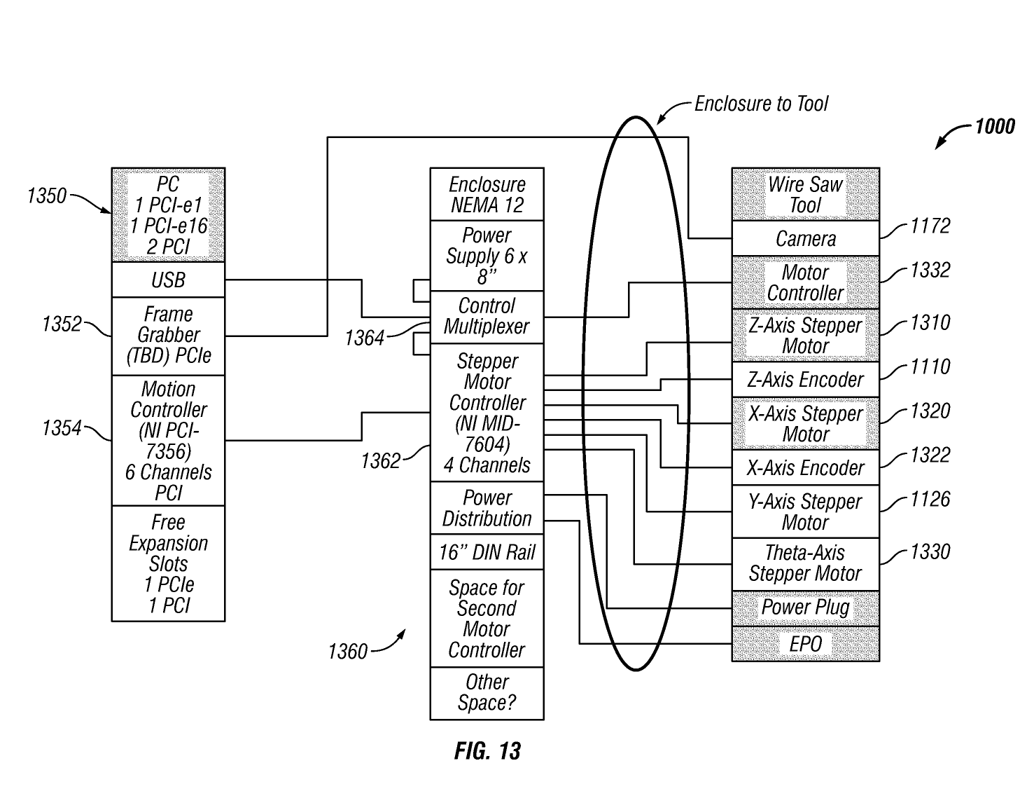

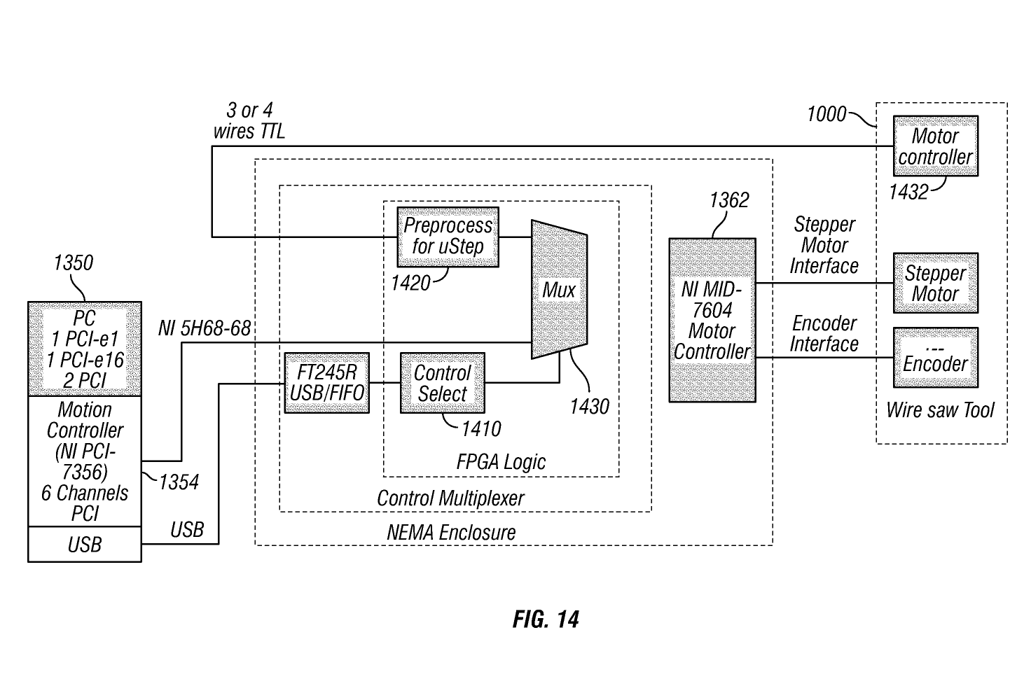

FIG. 13 illustrates one embodiment of a control system for cutting machine 1000. Cutting machine 1000 can include camera 1122, z-axis motor 1310, z-axis encoder(s) 1110, x-axis motor 1320, x-axis encoder 1322, y-axis stepper motor 1126, y-axis encoder (not shown), theta-axis motor 1330, a theta-axis controller (not shown), tip and tilt stage motors and respective encoders (not shown). Additionally, cutting machine 1000 can include a motor controller 1332 to control the z-axis motor 1310 and the x-axis motor 1320 according to routines available on the RTS440 as provided. A management station 1350 can control tool 1000. According to one embodiment, management station 1350 can be a personal computer, laptop or other computing device having sufficient processing and memory to provide programmatic control for cutting machine 1000. Management station 1350, according to one embodiment, can be a computer running a Windows based operating system (Windows is a trademark of Redmond, Wash. based Microsoft Corporation), such as Windows XP or Windows Vista with SP1. However, any suitable computing device can act as a management station and, in various embodiments management station 1350 may be provided as a portion of cutting machine 1000. According to one embodiment, management station 1350 can include software 1352 to receive and process image data from camera 1122. Additionally, management station 1350 can include a motion controller system 1354, such as the NI PCI 7356 6 channel motion controller by National Instruments of Austin, Tex. A GUI, MMI or other interface can be provided by management station 1350. For example, LabView 8.5.1 by National Instruments can be used to provide a user interface for controlling cutting machine 1000. The interface can provide, for example, a live view camera image window internal to LabView with an image window to have adjustable crosshairs in vertical and horizontal. Position control buttons/window can provide for commanding movement of and indicating positions. Screen indicators can show the completion of any commanded movement. Various stages may also be commanded by an onscreen “joystick” or other type of control for interactive motion of the systems.

According to one embodiment, management station 1350 can interface with a motor control system 1360 that can include a stepper motor controller system 1362, such as the National Instruments NI MID 7604 4 channel motor controller. The stepper motor controller system 1362 can interface with the stepper motors and encoders of cutting machine 1000 to retrieve data from encoders and forward motor control signals to the various motors. Additionally, motor control system 1360 can include a control multiplexer 1364 discussed below. Motor control system 1360 can have a variety of form factors and can be enclosed in a NEMA housing.

In general, management station 1350 can generate commands to stepper motor controller system 1362, which can, in turn, generate motor control signals to control the various motors of cutting machine 1000. In some cases, commands and data can be forwarded to the motor control system provided by cutting machine 1000 if the user wishes to use the built-in motor control routines of cutting machine 1000.

FIG. 14 provides diagrammatic representation of a motor control system for one axis of movement and a motor control system 1360 to control motion for cutting sidewall shapes. While control for only one axis is shown, motor control system 1360 can control multiple motors (e.g., a z-axis, y-axis, x-axis, theta-y axis, theta-z axis, theta-x axis motors or other motors). Motor controller system 1360 can include control select logic 1410 that determines whether a command is forwarded to the motor controller 1332. Microstep preprocessor logic 1420 can preprocess signals sent to motor controller 1332 to allow motor controller 1332 to take smaller step sizes than available with the onboard programming of the RTS440. Otherwise, signals for various motors can be multiplexed at multiplexer 1430 and be provided to stepper motor controller system 1362. Stepper motor controller system 1362 can interface with the various motors and encoders to cause cutting machine 1000 to operate according to routines that are not available to controller 1332 that is supplied with cutting machine 1000. For example, the various motors of cutting machine 1000 can be operated to cause the cutting wire to cut a sidewall shape for a device as described above. Such motion is not available to standard motor controllers of wire cutting machines as wire cutting machines generally make straight cuts.

While motor control in FIGS. 13 and 14 are shown to be distributed, in other embodiments management station 1350 can interface directly with a motor controller of cutting machine 1000 to programmatically control cutting machine 1000. In yet other embodiments, cutting machine 1000 can provide a user interface that allows control of cutting machine 1000 to cut the desired sidewall shapes.

While, in the above embodiments, the example of particular cutting machine is used, it should be understood that other suitable cutting machines can be modified or designed to allow movement of the wafer and cutting wire relative to each to create the desired sidewall shape. While various parts and features have been described, it should be understood that such parts and features are exemplary and any cutting machine that can cut sidewall shapes as described above can be used.

During operation of a wire saw, the components of cutting machine 1000 may be exposed to a flow of coolant, such as deionized water. Additionally, particulate matter will be removed from the wafer. The various components can be selected to be sealed to protect against water and particulate matter.

While FIGS. 10-14 provide a particular example embodiments of a wire cutting machine, it should be understood that these embodiments are provide by way of example and not limitation. In other embodiments, for example, multiple wires can be used to cut rows of sidewalls simultaneously.

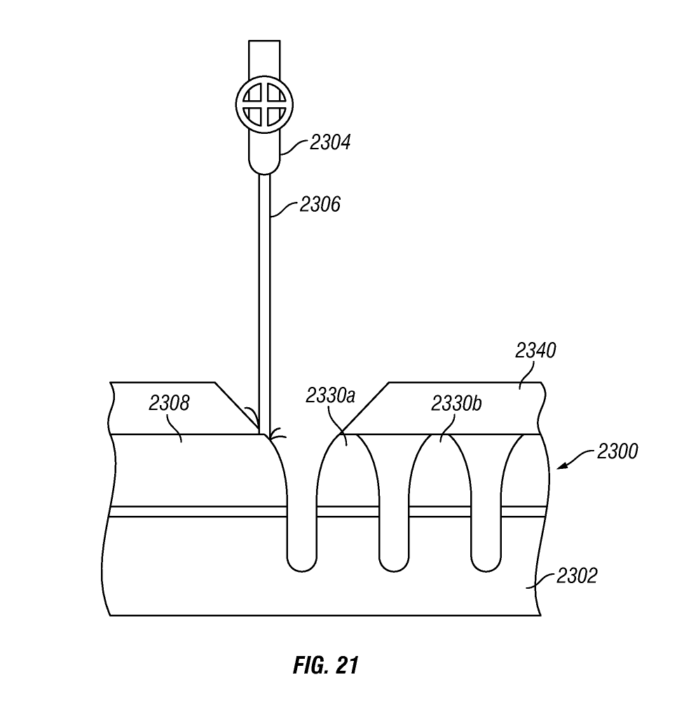

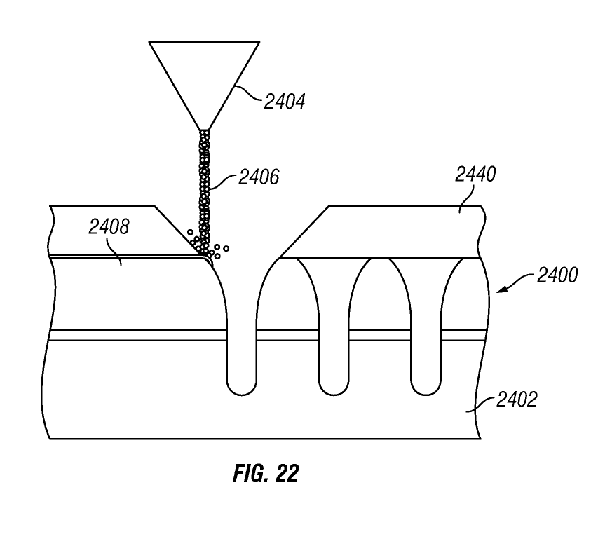

When using diamond coated wire, there is typically no free-abrasive, so the active areas of the die are not exposed to abrasive action. Alternatively, a plain wire with free-abrasive slurry may also be used to generate the shape. In such a case, precautions can be taken to protect the active area of the die from the free-abrasive. For example, a cover can be used to protect the active areas of the die while providing slots through which the wire can move to cut the wafer. Embodiments of covers are discussed below in conjunction with FIGS. 21 and 22. In other embodiments, a protective layer of material can be applied to protect the die.

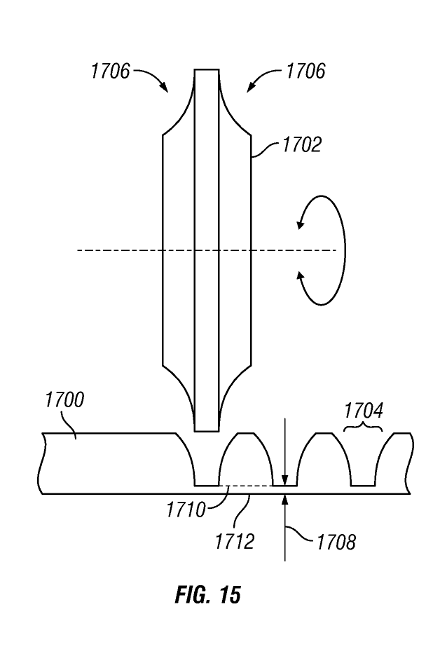

Another method of producing shaped sidewalls is to use a grinding process. FIG. 15 is a diagrammatic representation of one embodiment of grinding a die with a shaped abrasive wheel 1702. According to the embodiment of FIG. 17, a wafer 1700, which may be prepared for shaping as discussed above, is mounted on a work surface. Abrasive wheel 1702 is rotated at high speed and brought in contact with wafer 1700. The composition of the abrasive wheel can depend on the substrate being cut, wear and other factors. Abrasive wheel can be a metal composite, vitreous, resin based wheel or other type of wheel. As one example, a metal (Ni—P alloy) blade with a diamond or other abrasive particle matrix having a selected particle size can be used to cut sapphire. The particle matrix in an embodiment has an average size of 20 microns, though other particle sizes can be used. The shaped wheel 1702 has shaped regions 1706 that are shaped to remove material from wafer 1700 in a desired pattern. According to one embodiment, shaped regions 1706 are shaped to cut the substrate to the desired substrate shape.

As material is removed from wafer 1700 by shaped wheel 1702, abrasive wheel 1702 is lowered to a desired depth to create channel 1704. In other embodiments, a series of wheels 1702 can be used with each wheel having shaped regions 1706 that are successively closer to the inverse of the desired LED shape. By making multiple passes, a sidewall can be made closer to the desired shape.

Either or both of the wafer and grinding wheel are moved back and forth until the desired depth of cut is achieved. Once all the streets (channels) are cut in one direction, the wafer can be rotated 90 degrees and the cuts are made in the other direction, producing a rectangular array of shaped substrates. Because of the high forces required in grinding, it can be difficult to keep the devices in alignment if the wafer is cut all the way through. Therefore, a web of material 1708 can be left to leave various devices in the array attached to each other. By way of example, but not limitation, the web can be approximately 175 to 200 microns thick. The web can be removed in subsequent processing. In other embodiments, the web can remain. In such a case, the shape of the substrate can be selected using the entrance to the web portion as the exit face of the LED (e.g., indicated by 1710). Because the sidewalls can be designed so that light does not TIR (or TIR is reduced) if region 1710 was in fact the exit face, the light will not TIR at surface 1712 of the web.

While shaped wheel 1702 is shown with shaped regions 1706 on both sides, shaped wheel 1702 may only have a shaped region 1706. In such a case, multiple passes may be needed to shape sidewalls on both sides of channel 1704. In other embodiments, multiple parallel wheels may be used to simultaneously cut multiple channels.

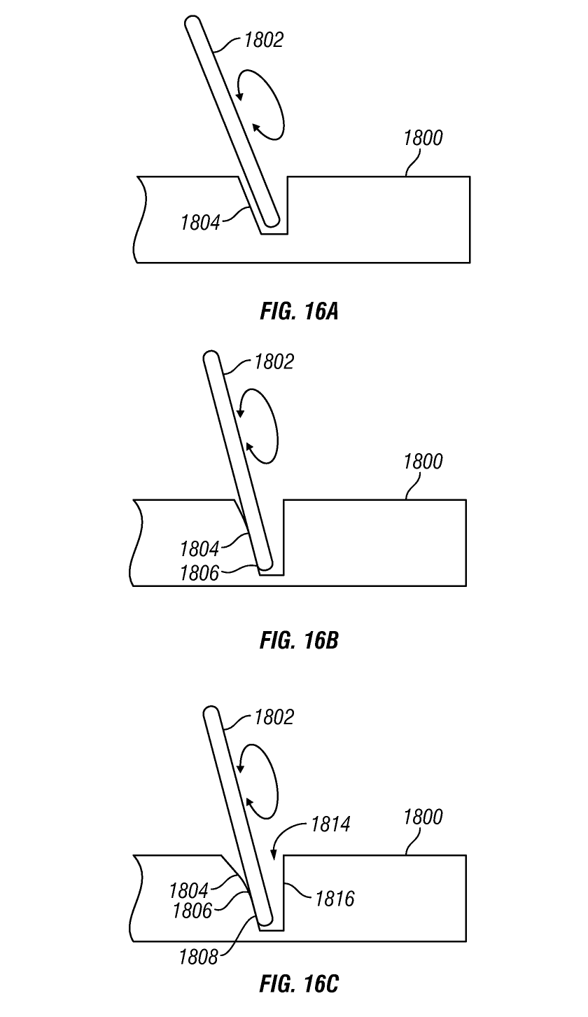

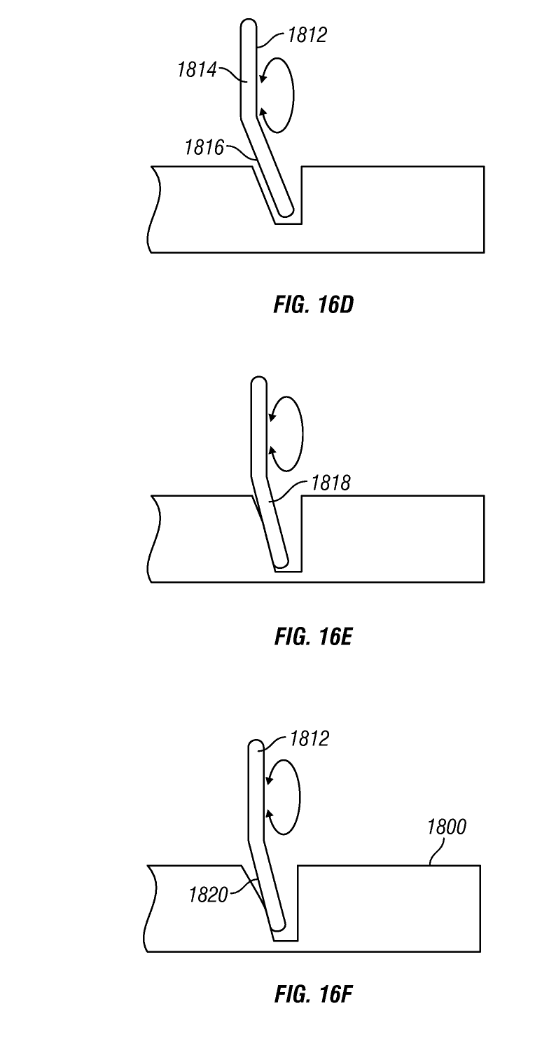

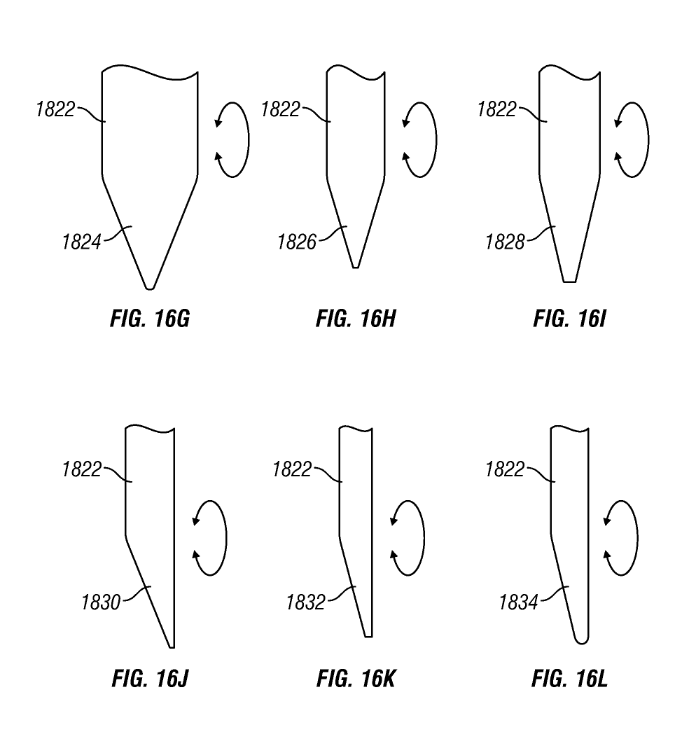

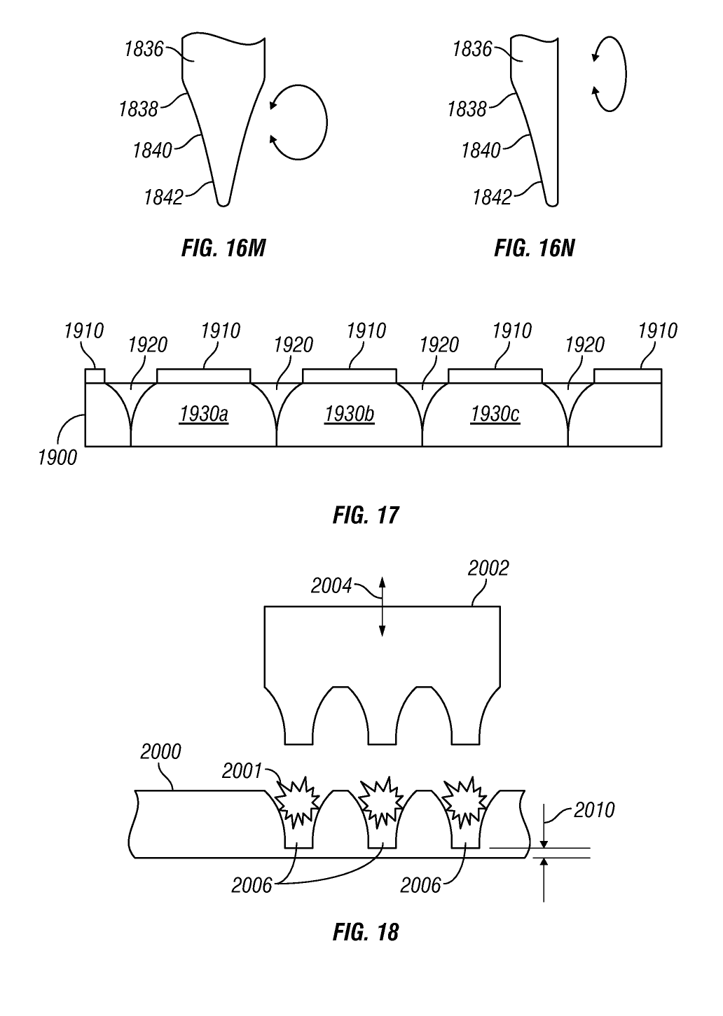

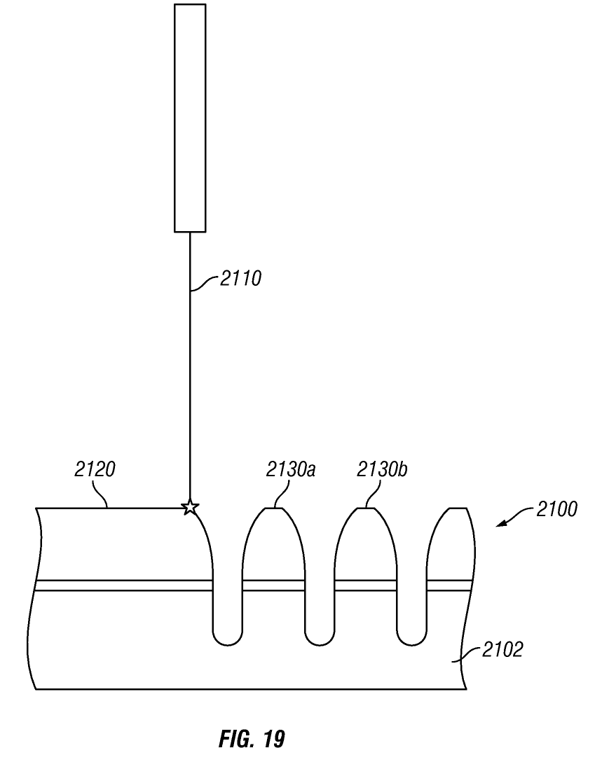

According to another embodiment, unshaped grinding wheels (e.g., grinding wheels without shaped region 1706) can be used to cut a desired number straight facets in the substrate material. FIG. 16A-C illustrates one embodiments of using an unshaped grinding wheel to cut facets in a substrate. In the embodiment FIG. 16A, a wafer 1800 is mounted on a work surface. An abrasive wheel 1802 is rotated and brought in contact with wafer 1800. As material is removed from wafer 1800 by wheel 1802, wheel 1802 is moved to a desired depth to create cut 1804. This process can be repeated for any number of additional angles to create facets. In FIG. 16B, wheel 1802 is angled relative to its position in FIG. 16A and again moved a desired amount to create cut 1806. Similarly, in FIG. 16C, wheel 1802 is angled relative to its position in FIG. 16B and moved a desired amount to create cut 1808. Again, as shown in FIG. 16C, the cuts can be made to optionally leave a small web of material.

Multiple passes can be made or multiple wheels used to cut rows of sidewalls. Wheel 1802 can then be angled, or another wheel used, to cut on the other side of channel 1814. Once channels running in one direction are complete, channels can be cut in the perpendicular (or other direction). Sidewalls can also be cut in other orders.

In one embodiment, the three cuts for a sidewall (e.g., cut 1804, 1806 and 1808) can be made at the following angles 1, 7 and 20 degrees from the vertical. The sidewalls can then be curved through polishing to create a curve with a desired profile or the number of the cuts and their angles can be selected to create a faceted sidewall. While, in this example, three facets are used, any number of facets can be chosen and cut.

Additionally, the cuts can be made using any desired cutting mechanism, such as a wire saw, ultrasonic milling or other mechanism.

In the example of FIGS. 16A-C, a grinding wheel with straight sides is used. As shown in the embodiments of FIGS. 16D-F, the same angles can be cut using grinding wheels with angled portions rather than angling the entire wheel. In the embodiments of FIG. 16D, for example, grinding wheel 1812 can include two sections 1814 and 1816. Section 1814 can have any desired profile, such as that of typical straight grinding wheel. The outer region forming section 1816 can also be straight, but can be angled at a desired angled so that grinding wheel 1812 makes cuts into the substrate material at the desired angle. Grinding can be repeated with different wheels for each angle. For example, rather than section 1816, the grinding wheel can have section 1818 as shown in FIG. 16E at a different angle than section 1816 or section 1820 in FIG. 16F at a different angle than sections 1816 or 1818.

FIGS. 16G-L are diagrammatic representations of portions of other embodiments of wheels 1822 with sections to cut similar angles as shown in FIGS. 16D-F.

In the embodiments of FIGS. 16G-I, wheel 1812 includes sections 1824, 1826 and 1828 corresponding to sections 1816, 1818 and 1820 of FIGS. 16D-F. Additionally, the embodiments of FIGS. 16G-I include an angled section on the other side of the wheel to shape both sides of a channel at once. The embodiments of FIGS. 16J-L include sections 1830, 1832 and 1834 corresponding to sections 1816, 1818 and 1820 of FIGS. 16D-F. Thus, various shapes of grinding wheels with angled sections can be used to make straight cuts.

In the foregoing embodiments, the grinding wheel cut a single angle in the substrate material. In other embodiments, however, the grinding wheel can cut any number of desired angles. FIGS. 16M-N are diagrammatic representations of one embodiment of a wheel 1836 with multiple angled sections, such as sections 1838, 1840 and 1842, on one or both sides to create multifaceted sidewalls with one wheel. While only three facets are shown, more facets can be created. Furthermore, shaping using grinding wheels can occur using multiple grinding wheels with various configurations as needed or desired. One advantage of the embodiments of FIGS. 16D-N and FIG. 15 is that the spindle or other components driving the grinding wheel can remain in a fixed orientation.

Etching describes a chemical process of removing substrate material in a highly controlled manner as to yield the appropriate shape. There are typically two types of etching methods: wet etching and dry etching. Wet etching involves using liquid-phase etchants to remove the substrate material. In dry etching, plasma etching and reactive ion etching, ions are created and imparted onto the substrate. There, either based on chemical reaction or particle momentum, material is removed from the substrate.

Starting with a wafer of substrate material (that may further include material comprising the quantum well region), a particular pattern of photoresist can be deposited on a side of the wafer. The wafer is then etched. Locations on the wafer covered with the photoresist would not be etched, whereas places without the photoresist would have material removed. There are many ways to tune the process to achieve the desired contour at the edge of the photoresist. For example, thicker layers of photoresist can be applied and then sacrificially removed during the etching process, or other sacrificial layers can be used in conjunction with the photoresist. These layers are removed over time by the etchant in such a manner as to produce the desired contour of the LED substrate. This can be exploited to accurately etch the wafer so as to produce shaped substrates. Another way is to use multiple resists and multiple etching steps. Each photoresist and etch step can be used to remove a small layer of material. Multiple small steps can be use get the desired 3D shape.

FIG. 17 is a diagrammatic representation of an example of etching. In FIG. 17, wafer 1900 is etched to form shaped substrates 1930a-1930c. Photoresist 1910 is applied to a surface of wafer 1900 in a desired pattern such that portions of the surface of wafer 1900 are covered with photoresist 1910. Subsequent to the application of photoresist 1910, an etchant is applied to the same surface of wafer 1900 that the photoresist was applied. The etchant removes substrate material 1920, forming shaped substrates 1930a-1930c. Photoresist and etchant can be applied in successive layers and patterns to achieve a desired sidewall shape.

Etching parameters may be based on the substrate material. The etch rate varies depending on the etchant and the substrate. For substrate materials used in LED applications such as sapphire and silicon carbide, the etch rates using reactive ion etching can range from 250 nm to 2.5 um per min. Silicon carbide is on the upper end of the above etch rate while sapphire is on the lower end. One advantage of an etch process is that it can achieve a satisfactory surface finish that does not require subsequent polishing.

Another method of forming the sidewalls is to use ultrasonic shaping. According to one embodiment of ultrasonic shaping, ultrasonic shaping can utilize a shaped tool of a suitable hard material (e.g., aluminum or other material) that has one or more shaped bars. The shaped bars can be the shape of the material to be removed from the die. Abrasive slurry is applied to the die and the bars vibrated ultrasonically to cause the slurry to remove material from the substrate.

FIG. 18 is a diagrammatic representation of one embodiment of ultrasonic shaping. A wafer 2000 can mounted to a work surface. An abrasive slurry 2001 can be continuously applied to the surface of wafer 2000, wafer 2000 can be fully or partially submerged in the abrasive slurry 2001 or wafer 2000 can be coated in abrasive slurry 2001. Tool head 2002 is lowered until it is nearly in contact with the wafer. Tool head 2002 vibrates ultrasonically (indicated by arrow 2004) in a direction perpendicular to the plane of the wafer causing the abrasive particles in the slurry 2001 to cut channels 2006. While the direction of movement is shown as vertical in FIG. 18, wafer 2000 can be mounted in other orientations. Therefore the movement of tool 2002 may be in another direction, such as horizontal or at some angle. The frequency and amplitude of vibration can be selected based on the substrate material and other factors. As would be understood by those of ordinary skill in the art, ultrasonic tools used for cutting sapphire dies typically operate at above 17 kHz and generally around 20 kHz. The peak-to-peak amplitude is typically around 20 microns. However, any suitable frequency and amplitude can be used and the foregoing parameters are provided by way of example.

Tool 2002 is lowered into the wafer to the desired depth as the channels 2006 are continually worn away by abrasive slurry 2001. Tool 2002 can cut all the way through the substrate material or leave a web of material 2010 as described above. Generally, abrasive slurry 2001 can include any suitably sized particles of one or more suitable materials. By way of example, but not limitation, the slurry can be made of deionized water containing particles that are about 20-60 microns in diameter.

According to one embodiment, once all the streets in a single direction are created, the wafer is rotated relative to the tool and the streets in the other direction (typically orthogonal) are created. In other embodiments, a single channel 2006 can be cut at a time. According to yet another embodiment, tool 2002 can have a “waffle” shape that allows all the sidewalls to be cut at once.

According to another embodiment, laser ablation can be used. Laser ablation is the process of using a high power laser to produce LEDs by removing or ejecting quantum well region or substrate material. Each laser pulse will only remove a minute amount of material. The laser can be translated to remove material with each subsequent pulse. By translating in the X-Y and Z directions, a 3D shape can be removed. FIG. 29 is a diagrammatic representation of laser ablation. In the example of FIG. 29, a wafer 2100 is optionally mounted to a support material 2102. Laser 2110 is applied to wafer 2100 to ablate substrate material 2120, forming shaped substrates 2130a, 2130b and so on. Using known techniques, laser ablation can remove around 500 um to 1 mm in thickness per minute in silicon carbide and sapphire.

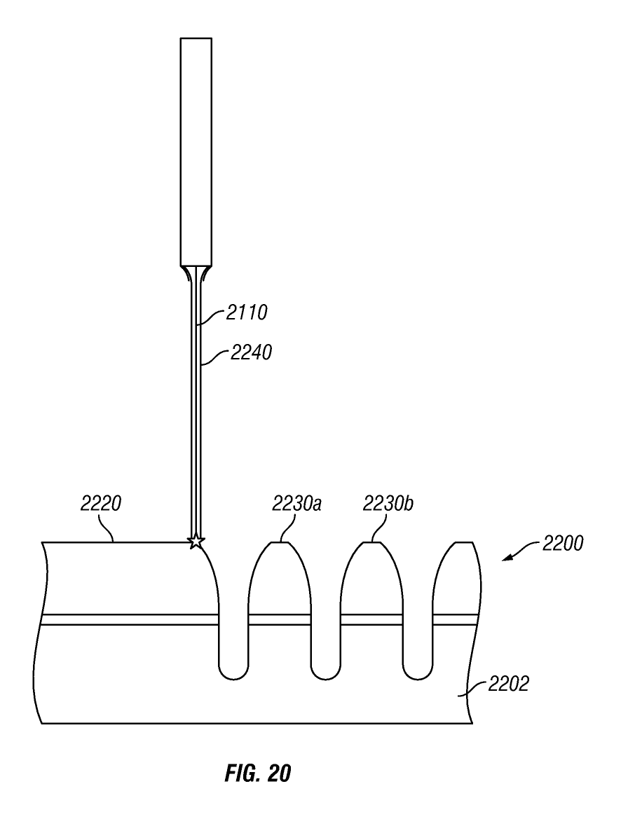

FIG. 20 is a diagrammatic representation of another embodiment of a system for laser ablation. In the embodiment of FIG. 20, wafer 2200 is mounted to support structure 2202. Laser 2210 is applied to wafer 2200 to ablate substrate material 2220, forming shaped substrates 2230a-2230b. In the embodiment of FIG. 22, a column of water 2240 acts as a waveguide for laser 2210. One advantage of using a water column waveguide is that the water column can act to cool substrate material 2220 and carry away removed material. However, other embodiments can utilize other waveguides, such as a fiber optic waveguide.

According to yet another embodiment, a water jet may be used to ablate a wafer to form a substrate of the desired shape. FIG. 21 is a diagrammatic representation of one embodiment of water jet cutting. As depicted in FIG. 21, a wafer 2300 is mounted on support structure 2303 and placed on a work surface. A water jet 2304 provides a continuous stream or short pulses of water 2306 that is of sufficient velocity to ablate a substrate 2308 in stages. The process by which pulses of water are used to ablate a wafer may be similar to the process described above in regard to laser ablation. In one embodiment of water jet ablation, the water jet can be used to cut completely through the wafer at a certain angle, then the angle shifted slightly and the water jet used to cut through the wafer at a slightly higher angle, eventually producing shaped substrates 2330a, 2330b and so on. In a further embodiment, the water jet may be charged with abrasive material (e.g. industrial diamond particles) to increase the rate at which material is ablated. The size of the particles can be selected to create a sidewall shape having a specified smoothness. For example, particles can be approximately 20-60 microns or other selected size. A cover 2340 can be used to protect areas of the wafer from water jet 2306 and any particulate matter. Cover 2340 can have openings spaced to allow water to impinge on wafer 2300 while protecting the electrical areas of the optical devices being formed. In addition to providing protection, cover 2340 can be used to restrain wafer 2300 in the tool.

According to another embodiment, a particle jet can be used to ablate substrate material. FIG. 22 is a diagrammatic representation of particle jet ablation. In the embodiment of FIG. 22, a wafer 2400 can be mounted to a support structure. A source 2404 can provide a stream of particles 2406 that impinge on wafer 2400 to remove material from substrate 2408. Stream of particles 2406 can be used to cut completely through the wafer at a certain angle. Multiple passes can be made to cut the wafers at higher angles, eventually producing a substrate of the desired shape. The size of the particles can be selected to create a sidewall shape having a specified smoothness. For example, particles can be approximately 20-60 microns or other selected size.

Depending on the particle size, power of the particle jet and other factors, particle jet 2406 may have a characteristic angle that is too large to form all the facets of a sidewall. However, because of the fast material removal provided by a particle jet, it can be advantageous to use a particle jet for bulk material removal or for starting the shaping process and use other methods such as etching, ultrasonic machining or grinding for finishing the sidewalls.

A cover 2440 can be used to protect areas of the wafer from the stream of particles 2406. Cover 2440 can have openings spaced to allow particles to impinge on wafer 2400 while protecting the electrical areas of the optical devices being formed. In addition to providing protection, cover 2440 can be used to restrain wafer 2400 in the tool.

While the above methods of ablating a wafer of material to form shaped substrates have been described individually, the above methods may be combined. For example, particle stream ablation or water jet ablation can be used for bulk material removal in a first pass and then ultrasonic cutting, milling, grinding, etching or other method can be used for more accurate shaping. The various methods can be used in any order to shape the optical devices.

Similarly, various other combinations of methods and techniques for removing substrate material from a wafer to produce LEDs can be used as appropriate depending on the substrate material. In addition, other methods, such as ultrasonic machining can be used to form shaped substrates. Additionally, techniques such as ultrasonic milling can be used.

While this disclosure describes particular embodiments, it should be understood that the embodiments are illustrative and that the scope of the invention is not limited to these embodiments. Many variations, modifications, additions and improvements to the embodiments described above are possible. For example, the various ranges and dimensions provided are provided by way of example and LEDs may be operable within other ranges using other dimensions. By way of example, while shaped substrates have been described in regard to sapphire and silicon carbide, other substrates that allow the passage of light may be used. For example, substrates may be made of glass or diamond. In one embodiment, substrates may be molded from moldable glass, providing a cost effective and easily shaped substrate. It is contemplated that these variations, modifications, additions and improvements fall within the scope of the invention as detailed in the following claims.

What is claimed is:

1. A method of manufacturing an optical device comprising:
providing a desired substrate shape for an optical device having a shaped substrate portion comprising:
an interface to a non-substrate layer adapted to receive light generated in a light emitting region of the optical device;
an exit face that has at least 70% of a minimum area necessary to conserve radiance for a desired half-angle of light projected from the LED, wherein the exit face is a select distance from the interface;
a set of sidewalls, each sidewall positioned and shaped to cause at least a majority of rays having a straight transmission path from the interface to that sidewall to reflect to the exit face with an angle of incidence at the exit face at less than or equal to a critical angle at the exit face;
shaping a substrate material based on the desired substrate shape to form shaped substrate portions of one or more optical devices.

2. The method of claim 1, wherein shaping the substrate material comprises:
providing an abrasive slurry;
vibrating a tool at ultrasonic frequency to cause the abrasive slurry to ablate the substrate material in multiple rows.

3. The method of claim 1, wherein shaping the substrate material comprises:
directing a laser to the substrate material using a water column;
ablating material from the substrate material using the laser.

4. The method of claim 1, wherein shaping the substrate material further comprises ablating the substrate material using a particle jet.

5. The method of claim 1, further comprising:
mounting a wafer in a tool, wherein the wafer comprises the substrate material; and
protecting portions of the wafer to prevent damage to those portions during shaping.

6. The method of claim 1, further comprising mounting a wafer to a support structure, wherein the wafer comprises the substrate material.

7. The method of claim 6, wherein shaping the substrate material further comprises removing a portion of the support structure.

8. The method of claim 1, wherein shaping the substrate material further comprises leaving a web a material between shaped substrate portions for LEDs.

9. The method of claim 1, wherein shaping the substrate further comprises shaping the substrate using a wire saw.

10. The method of claim 1, wherein shaping the substrate further comprises cutting the substrate at select angles to form a sidewall using one or more straight grinding wheels.

11. The method of claim 10, wherein cutting the substrate at select angles to form a sidewall comprises cutting the substrate at three or more select angles.

12. The method of claim 11, wherein cutting the substrate at select angles to form the sidewall comprises cutting the substrate at eight or less select angles.

13. The method of claim 1, wherein shaping the substrate further comprises cutting the substrate at select angles to form a sidewall using three or more grinding wheels wherein each of the three or more grinding wheels are shaped with an angled section selected to cut the substrate at a desired angle.

14. The method of claim 1, wherein the exit face has minimum area necessary to conserve radiance and the distance is a minimum distance so that all rays with a straight transmission path from the interface to the exit face will be incident on the exit face at less than the critical angle at the exit face.

15. A method of shaping an LED comprising:
providing a wafer comprising a substrate material and one or more layers for a quantum well region of the LED;
determining a desired substrate shape corresponding to an LED comprising:
an exit face opposite from and a distance from an interface to a non-substrate layer adapted to receive light generated in a light emitting region of the LED, the exit face having at least 70% of a minimum area necessary to conserve radiance for a desired half-angle of light projected from the shaped substrate; and
a set of sidewalls, wherein each sidewall is positioned and shaped so that at least a majority of rays having a straight transmission path from the interface to that sidewall reflect to the exit face with an angle of incidence at the exit face of less than or equal to a critical angle at the exit face; and
mounting the wafer to a support structure;
cutting the substrate material to form a shaped substrate portion of the LED based on the desired substrate shape.

16. The method of claim 15, wherein cutting the substrate comprises cutting the substrate with a wire saw.

17. The method of claim 15, wherein cutting the substrate comprises cutting the substrate at select angles to form a sidewall using one or more straight grinding wheels.

18. The method of claim 17, wherein cutting the substrate at select angles to form a sidewall comprises cutting the substrate at three or more select angles.

19. The method of claim 18, wherein cutting the substrate at select angles to form the sidewall comprises cutting the substrate at eight or less select angles.

20. The method of claim 15, wherein the exit face has minimum area necessary to conserve radiance.

21. The method of claim 15 wherein shaping the substrate further comprises cutting the substrate at select angles to form a sidewall using three or more grinding wheels wherein each of the three or more grinding wheels are shaped with an angled section selected to cut the substrate at a desired angle.
